(19) United States
(12) Patent Application Publication
(10) Pub. No.: US 2026/0123540 A1
(43) Pub. Date: Apr. 30, 2026

(54) BACK SIDE POWER DELIVERY FOR WAFER-SCALE INTEGRATION WITH AN ISOMETRIC GRID ARRAY WITH COMPRESSION PINS

(71) Applicant: Volantis Semiconductor, Inc., Portland, OR (US)

(72) Inventors: Kevin Nan Lam, Pleasanton, CA (US); Tapabrata Ghosh, San Francisco, CA (US)

(73) Assignee: Volantis Semiconductor, Inc., Portland, OR (US)

(21) Appl. No.: 19/177,834

(22) Filed: Apr. 14, 2025

Related U.S. Application Data
(63) Continuation-in-part of application No. 19/093,546, filed on Mar. 28, 2025.
Application No. 19/093,546 is a continuation-in-part of application No. 19/079,851, filed on Mar. 14, 2025.
Application No. 19/079,851 is a continuation-in-part of application No. 19/056,456, filed on Feb. 18, 2025.
Application No. 19/056,456 is a continuation-in-part of application No. 19/023,647, filed on Jan. 16, 2025.
Application No. 19/023,647 is a continuation-in-part of application No. 18/978,188, filed on Dec. 12, 2024.
Application No. 18/978,188 is a continuation-in-part of application No. 18/958,107, filed on Nov. 25, 2024.
Application No. 18/958,107 is a continuation-in-part of application No. 18/940,944, filed on Nov. 8, 2024.
(60) Provisional application No. 63/714,353, filed on Oct. 31, 2024.
(60) Provisional application No. 63/720,216, filed on Nov. 14, 2024.
(60) Provisional application No. 63/750,817, filed on Jan. 29, 2025.
(60) Provisional application No. 63/750,822, filed on Jan. 29, 2025.

(51) Int. Cl. H01L 25/065; H01L 21/48; H01L 23/00; H01L 23/40; H01L 23/473; H01L 23/538; H05K 1/18; H10D 80/30

(52) U.S. Cl. CPC H10W 90/00; H05K 1/181; H10D 80/30; H10W 40/47; H10W 40/611; H10W 42/121; H10W 70/023; H10W 70/027; H10W 70/611; H10W 70/635; H05K 2201/10325; H05K 2201/10522; H10W 40/60; H10W 90/724

(57) ABSTRACT

Disclosed techniques enable provide techniques for improved power delivery for wafer-scale integration. A wafer-scale integration interposer (WSII) is accessed. A front side of the WSII is bonded to a plurality of chiplets. The WSII includes through-silicon vias (TSVs).

Modular power substrates (MPSs) are inserted into an isometric grid array (IGA). A back side of the IGA includes a plurality of external compression pins. The MPSs are coupled to the chiplets. The coupling includes compressing, by one or more compression plates, one or more elastomer sheets between the MPSs and the TSVs. The compressing is based on the external compression pins. The MPSs are coupled to DC-to-DC power converters. The coupling is based on sockets. DC power is sent by the DC-to-DC power converters to the chiplets. The sending is based on the MPSs, the one or more elastomer sheets, and the TSVs.

### RELATED APPLICATIONS

This application is a continuation-in-part of U.S. patent application “Back Side Power Delivery For Wafer-Scale Integration With Laser Assisted Bonding” Ser. No. 19/093,546, filed on Mar. 28, 2025.

The U.S. patent application “Back Side Power Delivery For Wafer-Scale Integration With Laser Assisted Bonding” Ser. No. 19/093,546, filed on Mar. 28, 2025, is a continuation-in-part of U.S. patent application “Photonic Wafer-Scale Interposer With Tapered Waveguides” Ser. No. 19/079,851, filed Mar. 14, 2025.

The U.S. patent application “Photonic Wafer-Scale Interposer With Tapered Waveguides” Ser. No. 19/079,851, filed Mar. 14, 2025, is a continuation-in-part of U.S. patent application “Back Side Power Delivery For Wafer-Scale Integration With An Isometric Grid Compression Plate” Ser. No. 19/056,456, filed Feb. 18, 2025, which claims the benefit of U.S. provisional patent applications “Chiplet-Based Optical Wafer-Scale Network Switch” Ser. No. 63/750,817, filed Jan. 29, 2025, and “Wafer-Scale Integration Power Delivery With An Isotropic Conductive Adhesive” Ser. No. 63/750,822, filed Jan. 29, 2025.

The U.S. patent application “Back Side Power Delivery For Wafer-Scale Integration With An Isometric Grid Compression Plate” Ser. No. 19/056,456, filed Feb. 18, 2025, is also a continuation-in-part of U.S. patent application “Back Side Power Delivery For Wafer-Scale Integration With Solderless Modular Power Substrates” Ser. No. 19/023,647, filed Jan. 16, 2025, which claims the benefit of U.S. provisional patent applications “Cooling For Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Back Side Power Delivery For Wafer-Scale Integration With Solderless Modular Power Substrates” Ser. No. 19/023,647, filed Jan. 16, 2025 is also a continuation-in-part of U.S. patent application “Wafer-Scale Integration With A Stiffening Isometric Grid Array” Ser. No. 18/978,188, filed Dec. 12, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Wafer-Scale Integration With A Stiffening Isometric Grid Array” Ser. No. 18/978,188, filed Dec. 12, 2024 is also a continuation-in-part of U.S. patent application “Cold Plate Cooling For Wafer-Scale Integration With Back Side Modular Power Delivery” Ser. No. 18/958,107, filed Nov. 25, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film”Ser. No. 63/720,216, filed Nov. 14, 2024.

The U.S. patent application “Cold Plate Cooling For Wafer-Scale Integration With Back Side Modular Power Delivery” Ser. No. 18/958,107, filed Nov. 25, 2024, is also a continuation-in-part of U.S. patent application “Back Side Wafer-Scale Integration With Modular Power Delivery” Ser. No. 18/940,944, filed Nov. 8, 2024, which claims the benefit of U.S. provisional patent application “Cooling for Wafer-Scale Integration With Back Side Power Coupling”Ser. No. 63/714,353, filed Oct. 31, 2024.

Each of the foregoing applications is hereby incorporated by reference in its entirety.

### FIELD OF ART

This application relates generally to power delivery and more particularly to back side power delivery for wafer-scale integration with an isometric grid array with compression pins.

### BACKGROUND

The demand for energy such as electrical energy is growing significantly, indeed exponentially, worldwide. The increased demand results from expanding populations, wider availability and use of electrical and electronic devices, and the widely recognized need to transition from carbon-based energy sources. Demand has also increased as some cities, states, and countries encourage or force consumers to transition from carbon-based to electrical technologies for applications HVAC, lighting, cooking, and transportation, among many others. The increased electrical energy demand has also been driven by large datacenters as applications including artificial intelligence (AI) and cryptocurrency processing come online. These latter consumers can exceed all other consumers combined due to their immense computational requirements. As these energy demands grow worldwide, the search is on for new electrical energy sources. Among the leading contenders for electrical energy generation are hydropower, wind, and solar sources. Other contenders include geothermal generation, wave and tidal action, and so on. With the exceptions of hydro and geothermal generation sources, which can ideally operate 24×7, other “renewable” sources operate intermittently. Wind generation works only when the wind is blowing, solar generation when there is light, and so on. As a result, there is a significantly increased interest in improving energy storage technologies.

Among the many energy storage technologies that are being developed or improved, batteries are among the most commonly used storage elements. The batteries can store energy while the energy is being produced and can provide energy when energy sources are dormant. Thus, battery technologies have evolved to meet the increased power demands for previously mentioned applications, and for popular personal electronic devices. New batteries provide improved power density and faster charging times, among other benefits, compared to earlier battery types. Old technologies, including nickel-cadmium (NiCd) batteries, are being replaced by improved technologies and chemistries such as nickel-metal hydride (NiMH) and lithium-ion (Li-ion). These newer batteries offer higher power densities per unit volume, plus longer lasting and more stable power delivery. Another new battery type includes lithium-iron-phosphate (LiFePO4). This latter type provides increased power density and output, faster charging, and lower weight compared to other cells.

The increased demand for power sources worldwide presents a vast range of opportunities and challenges. Some countries are replacing their carbon fuel power plants with plants based on renewable energy sources. These latter energy plants include solar and wind farms, and geothermal plants, among others. Even with alternative energy generation, energy storage remains a major problem. For example, batteries are large, heavy, and expensive, and leak energy over time. Further, such alternative energy plants have to be located where the energy sources are the most abundant, including remote or lightly populated areas. Additionally, the existing energy distribution systems or “grids” are woefully inadequate to meet the increasing energy demands and for transferring energy from where it is generated to where it is consumed. Thus, publicly and privately funded projects that develop energy sources and update and expand energy distribution are desperately needed.

### SUMMARY

Computer users routinely demand faster computers and better applications. Further, the users demand device features that improve the usability of the devices. These device features now typically include biometric access, improved resolution cameras, and three-dimensional audio. These user requirements span the wide range of computing devices. Whether the computers are vast server farms or handheld devices such as smartphones, users always desire systems and devices that are faster and more capable than the systems and devices currently in use. As a result, circuit designers continue to design and to fabricate improved integrated circuits that present ever-increasing processing performance, expanded data processing options, and “product differentiating” features. The differentiating features now typically include larger or folding touchscreens, higher resolution cameras with multiple lenses, spatial audio that simulates different listening environments, biometric sensing for facial and fingerprint recognition, and “cute” applications from games to personal emoji generation, among many other enhancements. However, increasing chip processing speeds and other capabilities such as AI processing can force the addition of complex and large circuitry to the chips. To add new circuitry to the chips, designers employ two main design philosophies: increase the physical dimensions of the chip by making it larger, or increase circuit density by reducing feature sizes. These techniques have so far been successful in meeting the never-ending customer demands for increased performance. As a result, microprocessors, graphics processors, machine learning accelerators, systems-on-chips (SoCs), and so on currently boast transistor counts into the tens of billions. Concomitant with increasing performance, the architectural improvements and added devices increase the power density of the chips, resulting in prodigious heat generation.

Circuit architects, designers, and engineers have turned to wafer-scale integration to further address the never-ending drive for performance. In a perfect world, the chip would be the size of an entire wafer (which can be called a monolithic wafer), and the feature sizes would include greatly reduced transistor sizes, minimum contact sizes, smaller wire widths and separation, and reductions of all other dimensions related to circuitry. In another example, the wafer can form an interposer with bonded chiplets. Regardless of the methodology used to increase interconnection options, designers have considered through-silicon vias to provide direct connections between a front side of a chip (or wafer) and a back side of a chip. However, to reliably fabricate such interconnect, the wafers, for example, must be ground or polished to a thinness that supports the fabrication of the through-silicon vias. As a result, the thinned chips are prone to fracturing, not only because of the delicate nature of the materials of the wafer, but also because of the weights of the amassed elements bonded to, attached to, or otherwise connected to the wafers. Further, the coefficient of thermal expansion (CTE) can be different for various materials in a typical wafer stack-up leading to failures after power is applied and non-uniform expansion between elements. Finally, various connections to the wafer must be manufactured without rupturing other existing connections (for example, an oven typically used for a reflow process can damage chip connections such as controlled collapse chip connections (C4s)). Thus, proper support and stabilization of, power delivery to, connections to, and heat removal from the wafers have become paramount to prevent wafer damage or wafer failure.

Disclosed techniques enable back side power delivery for wafer-scale integration with an isometric grid array with compression pins. A wafer-scale integration interposer (WSII) is accessed. A front side of the WSII is bonded to a plurality of chiplets. The WSII includes a plurality of through-silicon vias (TSVs). Modular power substrates (MPSs) are inserted into an isometric grid array (IGA). A back side of the IGA includes a plurality of external compression pins. The plurality of MPSs is coupled to the plurality of chiplets. The coupling includes compressing, by one or more compression plates, one or more elastomer sheets between the plurality of MPSs and the plurality of TSVs. The compressing is based on the plurality of external compression pins. The plurality of MPSs is coupled to a plurality of DC-to-DC power converters. The coupling is based on a plurality of sockets. DC power is sent, by the plurality of DC-to-DC power converters, to the plurality of chiplets. The sending is based on the plurality of MPSs, the one or more elastomer sheets, and the plurality of TSVs.

A method for power delivery is disclosed comprising: accessing a wafer-scale integration interposer (WSII), wherein a front side of the WSII is bonded to a plurality of chiplets, wherein the WSII includes a plurality of through-silicon vias (TSVs); inserting, into an isometric grid array (IGA), a plurality of modular power substrates (MPSs), wherein a back side of the IGA includes a plurality of external compression pins; coupling the plurality of MPSs to the plurality of chiplets, wherein the coupling includes compressing, by one or more compression plates, one or more elastomer sheets between the plurality of MPSs and the plurality of TSVs, wherein the compressing is based on the plurality of external compression pins; coupling the plurality of MPSs to a plurality of DC-to-DC power converters, wherein the coupling is based on a plurality of sockets; and sending DC power, by the plurality of DC-to-DC power converters, to the plurality of chiplets, wherein the sending is based on the plurality of MPSs, the one or more elastomer sheets, and the plurality of TSVs.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for back side power delivery for wafer-scale integration with an isometric grid array with compression pins.

FIG. 2 is a flow diagram for mounting cold plates.

FIG. 3 is a diagram of a modular power substrate (MPS).

FIG. 4 is a top view of an isometric grid array (IGA).

FIG. 5 is a bottom view of an isometric grid array (IGA).

FIG. 6 is an illustration of reinforcement crossbars.

FIG. 7 illustrates a wafer with multiple die.

FIG. 8 illustrates inter-die interconnect for wafer-scale integration.

FIG. 9 shows inter-die interconnect and redundancy for wafer-scale integration.

FIG. 10 illustrates a flip-chip and interposer with flip-chips for wafer-scale integration.

FIG. 11 is an example of an elastomer sheet.

FIG. 12 is a cross-section of an apparatus for back side power delivery for wafer-scale integration with an isometric grid array with compression pins.

FIG. 13 is a system diagram for back side power delivery for wafer-scale integration with an isometric grid array with compression pins.

### DETAILED DESCRIPTION

Techniques using back side power delivery for wafer-scale integration with an isometric grid array with compression pins are disclosed. Demand for significant processing performance improvements has soared, correlating with the development of new applications for processors, accelerators, and so on. This demand places immense pressure on chip designers and chip architects to develop next-generation chips that can provide processing power to computers, servers, cloud servers, large language model (LLM) engines, etc. To meet these demands, vastly increased numbers of transistors have been added to a wide variety of chips such as systems-on-chip (SOCs). SOCs can include an immense range of circuitry which can include processors, memories, input/output (I/O) circuits, network switches, and other elements. These SOCs can be dimensionally large, possessing tens of billions of transistors. At the same time, the feature sizes of the transistors used for these large chips continue to shrink. In fact, according to Moore's law, the number of transistors that can fit into the same size chip should double every two years. While at some point, this doubling will likely end as the limits of lithography and physics are approached, in general, the “law” has held true for the last several decades. Keeping chip sizes roughly the same size while increasing transistor count is generally good news, but new technologies that drive smaller transistors also impose new challenges for designers. For example, as a transistor shrinks, leakage currents typically increase, driving larger power consumption for the chip. This effect, in combination with the active power required for billions of transistors, can drive extremely high-power densities for processors and other computing elements. Further, the wafers on which these large chips are fabricated are delicate. The wafers can fracture if the wafers are not properly handled and supported.

The tremendous increase of interest in and use of artificial intelligence (AI) applications, such as large neural networks, transformers, machine learning (ML) models, and so on, can require hundreds, thousands, or more processing elements. The processing elements handle, in some cases, trillions of computations required by the AI applications. These processing elements can include processor cores, multiprocessor cores, matrix computation accelerators, SOCs, ASICs, and so on. While multiple cores such as processor cores and memory cores can be included on the same chip, many chips, and thus, many processors, are required for executing these computationally intensive applications. The processing chips can be in communication with other processing chips that are located both locally and remotely. The processing chips are typically coupled via cards, data racks, and data centers. The chips, when taken together, introduce significant design challenges such as the provision of power to the chips, the cooling of all these chips, etc. For example, cooling has become a complex challenge, especially when thermal design power (TDP), a measurement of the maximum power consumed by a chip under normal operating conditions, continues to increase.

Technologies that improve performance of AI applications and models are actively being developed. One technique, wafer-scale integration, is an approach that holds great promise to address the highly demanding performance requirements, with a particular focus on the data transfer bandwidth needs of AI and other applications. Wafer-scale integration can include fabricating a monolithic wafer with any number of chips or using a wafer as an interposer to couple many chiplets. The chips can include AI accelerators; processors and multicore processors; SOCs; application-specific integrated circuits (ASICS); memory chips such as SDRAM, DDR1, DDR2, DDR3, DDR4, DDR5 and high bandwidth memory (HBM); and so on. The chiplets can be coupled by wiring paths within the wafer interposer. The wafer interposer can be processed using a back-end-of-line (BEOL) wafer process which can include any number of metal layers. These metal layers can be used to couple any AI accelerator to any memory controller on the interposer. The wafer metal layers can provide extremely high bandwidth communication between any element included on the interposer such as memory controllers, AI processors, etc., due at least in part to short communications paths. While such technology can address the performance challenges associated with extremely compute-intensive and high bandwidth applications such as AI acceleration, challenges exist for their use in production. For example, a wafer interposer can be brittle and difficult to handle, especially with a plurality of chiplets bonded to a front side. Further, the coplanarity of the wafer interposer can vary, resulting in less-than-optimal electrical connections across the front side and back side of the wafer interposer. Grinding of the interposer, which can enable technologies such as through-silicon vias (TSVs), can thin the wafer interposer, making it still more difficult to handle without cracking. A further challenge arises in the connections between all layers of the wafer-scale integration (WSI) system. For example, chips on the top of the interposer can be mounted using flip-chip techniques via controlled collapse chip connections (C4s), microbumps, and so on to the interposer. However, for delivering power, larger DC power transformers often require soldering to the back side of the interposer. The soldering process can include an oven which can crack or destabilize other C4s or microbumps attached to the interposer. A further complication is the difference in the thermal coefficient of expansion between a typical WSI stack-up, causing various elements to expand at different rates as temperatures rise due to operation. This can cause additional failures within a system. These issues present a substantial technical challenge for the handling, assembly, and operation of wafer interposers.

To address the significant risks while providing power to the wafer-scale integration interposer described above, back side power delivery for wafer-scale integration with an isometric grid array with compression pins is disclosed. A wafer-scale integration interposer (WSII) is accessed. A front side of the WSII is bonded to a plurality of chiplets. The WSII includes a plurality of through-silicon vias (TSVs). The TSVs provide connectivity between a front side of the WSII and a back side of the WSII. A plurality of modular power substrates (MPSs) is inserted into an isometric grid array (IGA). A back side of the IGA includes a plurality of external compression pins. A compression force can be applied to the plurality of external compression pins. The plurality of MPSs is coupled to the plurality of chiplets. The coupling includes compressing, by one or more compression plates, one or more elastomer sheets between the plurality of MPSs and the plurality of TSVs. The elastomer sheets include conducting filaments that provide conduction paths through the elastomer sheets. The compressing is based on the plurality of external compression pins. The plurality of MPSs is coupled to a plurality of DC-to-DC power converters. The plurality of DC-to-DC power converters can convert a first DC voltage to a second DC voltage. The coupling is based on a plurality of sockets. The plurality of sockets can include high-power sockets, DC sockets, etc. The plurality of DC-to-DC power converters sends DC power to the plurality of chiplets. The sending is based on the plurality of MPSs, the one or more elastomer sheets, and the plurality of TSVs.

The plurality of MPSs is coupled to a plurality of DC-to-DC converters. The plurality of DC-to-DC power converters can comprise a unified control board (UCB). The coupling can be based on a plurality of high-power sockets. The high-power sockets can include high-power DC sockets. The UCB includes the plurality of DC-to-DC power converters. The DC-to-DC power converters can convert a higher DC voltage to a lower DC voltage. The lower voltage can enable operation of the chiplets on the WSII. DC power is sent, by the UCB, to the plurality of chiplets. The sending is based on the plurality of DC-to-DC power converters, the plurality of MPSs, and the plurality of TSVs. The sending can include delivering the DC power, by the UCB, to the plurality of MPSs. The delivering can include a first voltage conversion.

The DC power that was delivered, by the plurality of MPSs, can be transferred to the plurality of chiplets. The transferring can include a second voltage conversion. The second voltage conversion can produce a DC voltage below a threshold such as 1 volt.

A first cold plate can be coupled, attached, etc. to the plurality of chiplets to cool the chiplets. A second cold plate can be coupled, attached, etc. to the plurality of DC-to-DC converters. Each of the cold plates comprises an inlet plate, a jet-plate, and a fin-plate. Coolant at a first temperature can be sent into at least one inlet nozzle located on the inlet plate. The sending can include spraying the coolant, by the jet-plate, onto the fin-plate. At least a portion of the heat that was created can be transferred, by the cold plate, to the coolant that was sent. The coolant can be captured, at a second temperature, from one or more outlet chambers within the jet-plate.

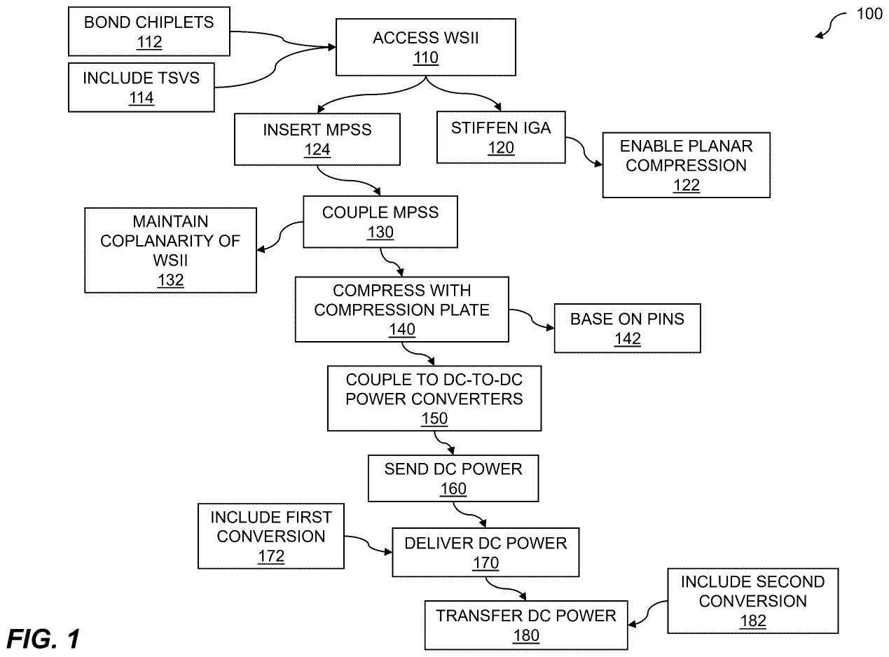

FIG. 1 is a flow diagram for back side power delivery for wafer-scale integration with an isometric grid array with compression pins. The flow 100 includes accessing a wafer-scale integration interposer (WSII) 110. Wafer-scale integration has been a long-sought goal of integrated circuit design. One objective of wafer-scale integration is that an entire wafer such as a silicon wafer (which can be a monolithic wafer) could be used to fabricate one large integrated circuit. However, since physical defects in the silicon wafer are distributed across the wafer, portions of circuitry which were fabricated over the defects would likely not function properly. In addition, errors that occur when fabricating the many layers that form the integrated circuit could further cause portions of the integrated circuit to likely not function. Instead, by attaching or bonding a plurality of integrated circuits to the WSII, wafer-scale integration can be achieved. This technique can further allow chips from different manufacturing processes to be included in the wafer-scale integration. In this case, the wafer can be used as an interposer to couple the various integrated circuits. The wafer can be a 300 mm wafer, a 200 mm wafer, or a wafer of another size. The wafer can comprise silicon or another suitable material. In a usage example, another suitable material can include glass. The wafer can include any amount of front-end-of-line (FEOL) processing and/or back-end-of line (BEOL) processing. The processing can be based on Complementary Metal-Oxide-Semiconductor (CMOS), Silicon on Insulator (SOI), Gallium Nitride (GaN), or another process.

In the flow 100, a front side of the WSII is bonded to a plurality of chiplets 112. The WSII can have a front side and a back side onto which elements such as the functional circuit elements can be attached, bonded, mounted, etc. The chiplets can include general purpose chips such as processor chips, multiprocessor chips, graphics processor chips, application-specific integrated circuits (ASICS), memory chips, switching chips, and so on. In a usage example, the plurality of chiplets includes one or more artificial intelligence (AI) accelerators. The AI accelerators can be used for applications such as machine learning; natural language processing; image, video, and audio processing; etc. In another usage example, the plurality of chiplets includes one or more memory devices. The plurality of chiplets can include one or more application specific integrated circuits (ASICS); one or more systems-on-chip (SOCs); optical components such as vertical-cavity surface-emitting lasers (VCSELS); I/O chips; switching chips; and so on. In the flow 100, the WSII includes a plurality of through-silicon vias (TSVs) 114. A TSV can include an electrical connection that completely passes through a wafer such as a silicon wafer, a glass wafer, a die cut from a wafer, and so on. The plurality of TSVs can be oriented vertically in order to enable connections between the front side of the wafer and the back side of the wafer. Chips such as the chiplets can be positioned such that connections to the chips align with the TSVs. In some examples, a wafer can be ground to enable TSV processing with repeatable shapes and parasitic characteristics.

In exemplary implementations, the WSII can comprise a monolithic wafer. The monolithic wafer can include a plurality of functional cores that are fabricated on the wafer. The functional cores can include one or more processors, AI accelerators, ASICS, peripheral interfaces, and so on. The functional cores can include memory. Other memory elements, such as SRAM, DRAM, etc., can be included in the monolithic wafer. The memory elements can also be fabricated on the wafer. Interconnect can be included on the monolithic wafer to couple any number of the functional cores, memory elements, and so on. The interconnect can comprise any number of metal layers on the wafer.

The WSII can be fragile. The TSVs can be difficult to fabricate because filling a small hole that extends from a front side of the WSII to a back side of the WSII can result in voids in a conducting material, resistive vias, and so on. To reliably fabricate the TSVs, the WSII wafer can be ground, polished, etc. in order to reduce the thickness of the WSII. However, reducing the thickness of the WSII can render the WSII even more susceptible to fracture, warping, and the like, particularly when the plurality of chiplets is bonded to the WSII. The weight of the chiplets further leads to risk of fracture and/or warping. In order to mitigate these risks to the WSII, an isometric grid array (IGA) can provide stiffening for the WSII. The WSII can be inserted into a front side of the WSII which can include a recess to accept the wafer. The IGA can include a plurality of open recesses through which additional elements can be coupled to the back side of the WSII. The walls of the open recesses within the MPSs can be sufficiently thin to minimize consumption of WSII real estate by the IGA. The walls of the IGA can further be strong enough to support and stiffen the WSII, thereby substantially reducing the risk of fracturing the WSII. Embodiments include stiffening the IGA 120, wherein the stiffening is based on a plurality of reinforcement crossbars within one or more open recesses within the IGA. The IGA can comprise a grid of open recesses. The open recesses can include a variety of shapes, where the shapes of the open recesses can be based on shapes of one or more chiplets. The open recesses can include square recesses, rectangular recesses, round recesses, oval recesses, honeycomb (e.g., hexagonal) recesses, etc. The reinforcing of the IGA can also be based on a reinforcement ring, a reinforcement crossbar, and so on within one or more open recesses within the IGA. One or more external compression pins can be coupled to a back side of the IGA.

Discussed in further detail below, elastomer sheets can be used to couple one or more MPSs to one or more TSVs on the back side of the WSII. The coupling can enable back side power delivery to the WSII. In order to form reliable connections, the elastomer sheet can be compressed by one or more compression plates. In embodiments, the plurality of reinforcement crossbars and the plurality of external compression pins enable planar compression 122 of the one or more elastomer sheets. The planar compression can enable compression to be applied substantially equally to elements attached, bonded, or otherwise coupled to the WSII. The external compression pins associated with the IGA can provide support for planar compression of the WSII when in contact with a compression plate. Without the external compression pins, when the IGA is compressed by one or more compression plates, the middle of the IGA may “sag,” providing less compression force than is received by the edges of the IGA. In some circumstances, this can lead to an unreliable electrical connection between the MPSs and the WSII in the middle of the IGA, causing unreliable power delivery to the chiplets. The elastomer sheets can include conducting filaments which can provide a conduction path between a front side of the elastomer sheet and a back side of the elastomer sheet. Filaments that come in contact with pins, pads, etc. associated with the WSII and an element bonded, mounted, etc. to the WSII provide the conduction paths. Filaments that do not come in contact with the pins, pads, etc. can remain unused.

The flow 100 includes inserting 124, into an isometric grid array (IGA), a plurality of modular power substrates (MPSs), wherein a back side of the IGA includes a plurality of external compression pins. The plurality of open recesses associated with the IGA can be substantially similar in size and shape to the plurality of MPSs. The reinforcement crossbars associated with the open recesses within the IGA can make contact with the MPSs that are inserted into the IGA. The compression pins can transfer compression force provided by one or more compression plates to the IGA, which can compress the elastomer sheets between the MPSs and the WSII. The flow 100 includes coupling the plurality of MPSs 130 to the plurality of chiplets. The coupling can be accomplished using interconnect between contacts, terminals, pads, and so on associated with each MPS within the plurality of MPSs and contacts, terminals, pads, and so on associated with each chiplet within the plurality of chiplets. In embodiments, the coupling the MPSs to the chiplets is accomplished using the TSVs. In embodiments, the IGA maintains a coplanarity 132 of the WSII. Maintaining coplanarity of the WSII can improve the efficacy of electrically coupling the MPSs inserted into the IGA to the WSII.

In the flow 100, the coupling includes compressing 140, by one or more compression plates, one or more elastomer sheets between the plurality of MPSs and the plurality of TSVs. The one or more compression plates can apply a compression force on one side of the WSII or on both sides of the WSII. The compression force applied by the one or more compression plates can press contacts such as microbumps or C4s associated with each MPS into the one or more elastomer sheets. Recall that the elastomer sheets can include conducting filaments that are oriented vertically between a front side of an elastomer sheet and a back side of the elastomer sheet. When one or more filaments come in contact with a C4, for example, contact can be made between the C4 of the MPS and a solder bump, microbump, or C4 associated with the WSII. One or more filaments can make contact with one or more TSVs.

In embodiments, the compressing is based on the plurality of external compression pins 142. The external compression pins extending from the back side of the IGA can extend between the plurality of MPS to make contact with a compression plate. As described above, the external compression pins associated with the IGA can provide support for planar compression of the WSII. Without the external compression pins, when the IGA is compressed by one or more compression plates, the middle of the IGA may “sag,” providing less compression force than is received by the edges of the IGA. In some circumstances, this can lead to an unreliable electrical connection between the MPSs and the WSII in the middle of the IGA, causing unreliable power delivery to the chiplets.

The flow 100 includes coupling the plurality of MPSs to a plurality of DC-to-DC power converters 150, wherein the coupling is based on a plurality of sockets. The sockets can include high-power sockets. The high-power sockets can include pins, terminals, contacts, etc. that can include DC power, data input/output (I/O), control signals, and so on. In embodiments, the plurality of DC-to-DC power converters comprises a unified control board (UCB). The DC-to-DC converters can be stacked. Any number of voltage conversions can be included so that the chiplets receive power at an appropriate operating voltage. In a usage example, a first voltage conversion is accomplished by the plurality of DC-to-DC power converters. The connectors can include a high-power connector. The substrate associated with an MPS to which the electrical elements, connectors, and so on are mounted can include a variety of materials. One or more MPSs within the plurality of MPSs can comprise an organic substrate. An organic substrate can be based on organic materials such as organic materials used to manufacture printed circuit boards. The organic substrate materials can include paper cores impregnated with phenolic resin, woven or unwoven glass cloth impregnated with epoxy or cyanate ester among others, natural fibers, etc. One or more MPSs within the plurality of MPSs can comprise an inorganic substrate. An inorganic substrate can be based on silicon, glass with a similar coefficient of expansion to the MPS, etc.

The DC-to-DC power converters can convert DC power from a high voltage range to a low voltage range (e.g., buck conversion). In a usage example, the DC-to-DC converters can convert DC power from a high voltage range, such as 48 volts to 54 volts, to a lower voltage range, such as 12 volts to 13.5 volts. The higher voltage range can be a voltage range normally supplied to racks within a data center. In a usage example, the UCB comprises a printed circuit board (PCB). The UCB can include one or more materials. The materials associated with the UCB can include inorganic substrate materials, organic substrate materials, and so on. The organic substrate materials can include paper cores impregnated with phenolic resin, woven or unwoven glass cloth impregnated with epoxy or cyanate ester among others, natural fibers, FR-4, FR-5, etc. In a further usage example, one or more MPSs within the plurality of MPSs can include an inorganic substrate. The inorganic substrate materials can be based on a silicon glass. In another usage example, the PCB comprises ceramic. The ceramic associated with the PCB can include a coefficient of thermal expansion (CTE) similar to the WSII or other components. Similar CTEs can help to limit differences in lateral movement between layers due to heat during operation. For example, aluminum nitride can have a CTE that is close to silicon. In embodiments, the PCB comprises aluminum nitride. A PCB can perform well in circuit applications where the circuits require high current and generate substantial heat.

Each MPS within the plurality of MPSs can be based on a form factor mirroring one or more corresponding chiplets within the plurality of chiplets on the front side of the WSII. The form factor can be based on one or more parameters associated with the one or more corresponding chiplets. In a usage example, the form factor can be based on a coefficient of thermal expansion (CTE). The chiplets can generate copious heat while operating. Physical components such as substrates, WSIIs, etc. can expand when heated based on a coefficient of thermal expansion associated with each material. A coefficient of thermal expansion of the UCB can be different than a coefficient of thermal expansion of the WSII. The difference in expansion coefficients can cause connectors to disconnect, C4s to crack, physical strain within materials that can cause damage, etc. Thus, if the UCB is directly mechanically connected to a WSII, the lateral displacement due to differences in thermal expansion can cause mechanical failure. Choosing an appropriate form factor for the MPSs can reduce risks of fracturing the WSII due to differing CTEs associated with the chiplets bonded to the front side WSII and the MPSs coupled to the back side of the WSII. Further, the modularity of the MPSs can provide a flexible power delivery system to the chiplets which can accommodate different movements of the WSII and UCB due to thermal expansion. For example, an MPS at one side of the WSII can be decoupled from an MPS on the other side of the WSII, thus accommodating various movements across the WSII and UCB. Further, compliant connectors can be used to better tolerate lateral displacement caused by CTE differences. By attaching the plurality of MPSs to the back side of the WSII instead of the front side of the WSII, heat mitigation techniques can be applied to the front side of the WSII.

In a usage example, a plurality of elastomer sheets is used to couple the WSII to the MPSs. The plurality of elastomer sheets can include a variety of materials, configurations, and so on. The elastomer sheet can comprise a conductive filament, such as brass, gold, etc., embedded in a silicone rubber sheet, or another suitable material. The filaments can be embedded on a pitch. The pitch can be designed to match a connector array, such as a ball grid array (BGA) of the MPS. The elastomer sheet can be held in place with a compression force. An adhesive backing can be added to the elastomer sheet.

The flow 100 includes sending DC power 160, by the plurality of DC-to-DC power converters, to the plurality of chiplets, wherein the sending is based on the plurality of MPSs, the one or more elastomer sheets, and the plurality of TSVs. Recall that the plurality of chiplets is bonded to the front side of the WSII. The sending power can be further based on converting one or more DC voltages. In embodiments, the sending includes delivering the DC power 170, by the plurality of DC-to-DC power converters, to the plurality of MPSs, wherein the delivering includes a first voltage conversion 172. In a usage example, the first voltage conversion can include converting a voltage in a range such as 48 volts to 54 volts to a voltage in a lower range such as 12 volts to 13.5 volts. The first voltage conversion can be controlled by the control circuits included on the UCB. Other embodiments include transferring the DC power 180 that was delivered, by the plurality of MPSs, to the plurality of chiplets, wherein the transferring includes a second voltage conversion 182. The second voltage conversion can convert a voltage to a voltage below a threshold. The second voltage conversion can change the voltage that the chiplets receive to an appropriate operating level, such as less than 1 volt. The transferring can be based on a plurality of MPSs that can be bonded to the back side of the WSII. The second voltage conversion can be controlled by the control circuits included on the UCB. Chips such as the chiplets can be positioned such that connections to the chips align with the TSVs. In some examples, a wafer can be ground to enable TSV processing with repeatable shapes and parasitic characteristics.

Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors.

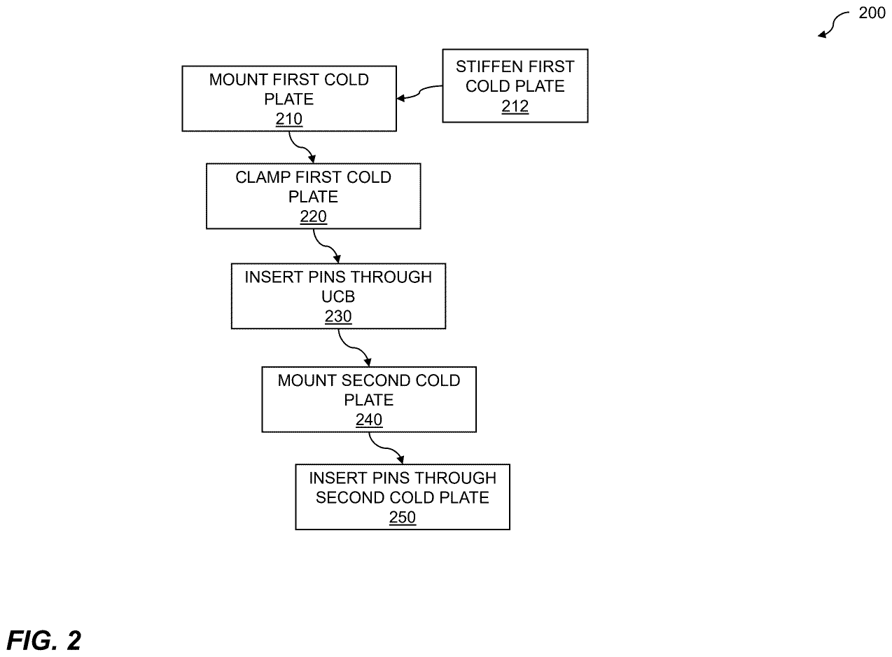

FIG. 2 is a flow diagram for mounting cold plates. Described previously, wafer-scale integration can be accomplished using a wafer-scale integration interposer (WSII). A top side of the interposer can be bonded to a plurality of chiplets, where the chiplets can include processors, multiprocessors, artificial intelligence accelerators, machine learning accelerators, switching chips, I/O chips, memories, and so on. The chiplets must be provided power such as DC power in order for the chiplets to operate. Modular power substrates (MPSs) can be coupled to a back side of the WSII with various conductive materials. The conductive materials can include elastomer sheets. Power to the chiplets can be provided by coupling the plurality of modular power substrates (MPSs) to a unified control board (UCB). The UCB can include DC-to-DC converters that can convert a DC voltage to a first DC voltage. The MPSs can further include DC-to-DC converters that can convert the first DC voltage to a second DC voltage. By coupling the plurality of MPSs to a back side of the wafer-scale interposer, the DC power can be provided by the MPSs on the back side of the interposer to the front side of the interposer using through-silicon vias (TSVs). Further, the above-mentioned methods and materials can enable coupling without the use of soldering techniques, such as wave soldering, which can bend, crack, weaken, etc. existing connections such as solder bumps, C4s, and so on.

Chips such as chiplets can be bonded to a wafer-scale integration interposer (WSII). The use of the WSII supports wafer-scale integration (WSI), which can be particularly useful to supporting the processing requirements of computationally intensive applications such as artificial intelligence (AI) acceleration or network switching. The chiplets that execute the computationally intensive applications can require significant amounts of power during operation. The power, which includes DC power, must be sent or transferred to the chiplets. The power can be provided using modular power delivery techniques. A WSII can be brittle and difficult to handle, especially with a plurality of chiplets bonded to a front side of the WSII. Further, the coplanarity of the WSII with respect to the UCB can vary due to heat dissipated by the chiplets and other elements, the weight of the chiplets and other elements, and so on, resulting in less-than-optimal electrical connections across the front side and the back side of the WSII. Additionally, to support of reliable manufacture of the TSVs, the interposer can be ground and/or polished to a thinness that can support fabrication of the TSV. This technique can thin the wafer, making it more difficult to handle without cracking, especially with the additional weight of front side chiplets. The MPSs can be supported or stiffened in order to protect the wafer-scale integration interposer from cracking or fracturing. An isometric grid array (IGA) with compression pins can be used to couple modular power substrates (MPSs) to a back side of the WSII. The IGA can be stiffened, where the stiffening can be based on a plurality of reinforcement structures. The reinforcement structures can include a plurality of crossbars, where the crossbars can be located within one or more open recesses within the WSII. The stiffening the IGA can be used to establish substantially equal compression across the MPSs. The reinforcement crossbars and the external compression pins can enable planar compression of one or more elastomer sheets. The elastomer sheets provide conduction paths between the MPSs and the WSII using filaments within the elastomer sheet.

The flow 200 includes mounting 210 a first cold plate to the plurality of chiplets. The first cold plate can provide liquid cooling based on distilled water or another liquid for the plurality of chiplets. The distilled water or other liquid coolant can be mixed with additives such as glycol. The mounting can include a thermal interface material (TIM). The TIM can conduct heat between surfaces, thus enabling more efficient cooling solutions. The TIM can comprise thermal tape, grease, gel, adhesive, phase change materials (PCMs), metal TIMs, pyrolytic graphite, and so on. In a usage example, the TIM can include an uncured TIM. The uncured TIM can remain flexible or viscous, thereby enabling the cold plate and the chiplets to expand by different lateral displacements based on different coefficients of thermal expansion. In embodiments, the first cold plate includes a plurality of internal compression pins, wherein the internal compression pins stiffen 212 the first cold plate. A first compression plate can exert pressure on the first cold plate. The pressure can be significant in order to compress the elastomer sheets sufficiently to form reliable connections to the MPSs. Since the first cold plate can include ports, internal channels, internal fins, and so on, the first cold plate could deform under compression. To counteract the possible deformation of the first cold plate, the internal compression pins can prevent cracking, deformation, warpage, etc. of the first cold plate when under compression stress from the first compression plate. Note that the internal compression pins associated with the first cold plate can be configured to align with external compression pins associated with the IGA (explained below).

The flow 200 includes clamping 220, based on one or more clamps, the first cold plate to a first compression plate within the one or more compression plates. The clamps can provide compression to enable a plurality of conductive connecting materials, such as elastomer sheets, to reliably couple the modular power substrates (MPSs) to one or more TSVs at the back side of the WSII. The clamps can be based on screws, bolts, nuts, and so on. In embodiments, the clamping is based on a second compression plate within the one or more compression plates, wherein the plurality of external compression pins contacts the second compression plate. Recall that a plurality of DC-to-DC converters can be coupled to a plurality of modular power substrates (MPSs). Recall also that a plurality of modular power substrates (MPSs) can be coupled to a back side of a WSII. The second compression plate can work together with the first compression plate to compress the WSII, the MPSs, and the UCB. As mentioned above, the compression can be based on a plurality of external compression pins. The external compression pins can be attached to the back side of the IGA and extend to the second compression plate. Thus, in embodiments, the clamping includes inserting 230, through a plurality of holes within the UCB, the plurality of external compression pins.

The flow 200 includes mounting a second cold plate. Embodiments include mounting a second cold plate 240 to the plurality of DC-to-DC power converters. As was the case for the plurality of chiplets bonded to the front side of the WSII, the DC-to-DC converters can generate copious heat while operating. By contacting the second cold plate to the DC-to-DC converters, a portion of the heat generated by the DC-to-DC converters can be extracted. In embodiments, the clamping includes inserting, through a plurality of holes within the second cold plate 250, the plurality of external compression pins. The external compression pins associated with the IGA can extend through the second cold plate to the second compression plate. The clamps can extend between the two compression plates in order to compress the first cold plate and the second cold plate, compress the WSII, and compress the IGA and the MPSs. The compressing can maintain a coplanarity of the WSII, as discussed above. The compressing can further enable reliable connections between the MPSs and the WSII via filaments within the one or more elastomer sheets such that power can be delivered to the plurality of chiplets through the back side of the WSII.

Various steps in the flow 200 may be changed in order, repeated, omitted, or the like without departing from the disclosed concepts. Various embodiments of the flow 200 can be included in a computer program product embodied in a non-transitory computer readable medium that includes code executable by one or more processors.

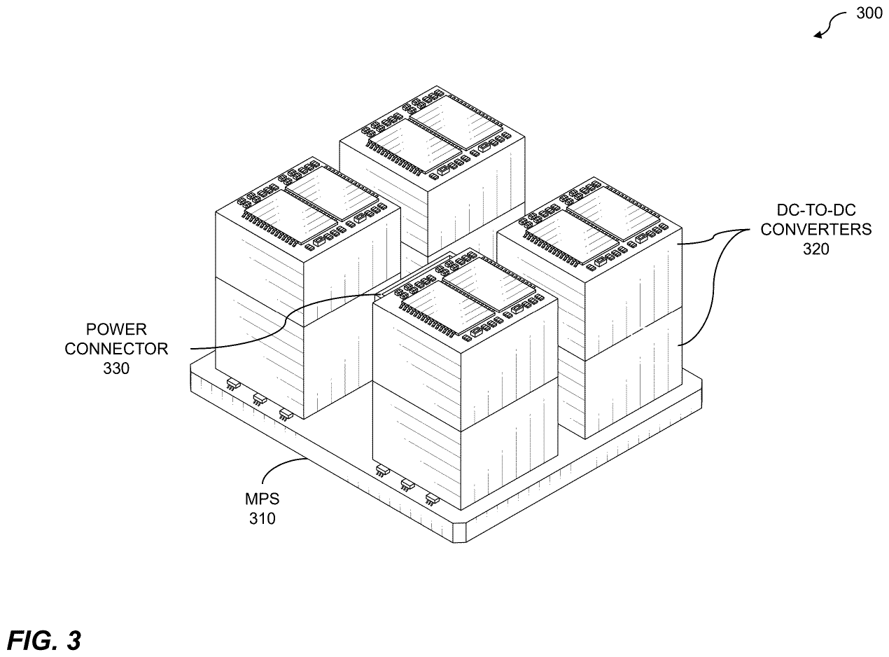

FIG. 3 is a diagram of a modular power substrate (MPS). Integrated circuits or “chips” such as processor circuits require power in order to operate. When a significant number of circuits is obtained to achieve an objective such as a complex processing objective, the power requirements for the many circuits become substantial, and the requirements for providing the power become more stringent. The power requirements can become more stringent as the aggregate power delivery to the chips can include tens, hundreds, or more amperes. Further, the many circuits to which the power is provided can generate copious heat. The heat generated by the various elements of a system such as power supplies, chiplets, and so on causes the elements to expand. Since the elements comprise different materials, coefficients of expansion of the elements can differ. To counter the potentially deleterious effects such as fracture resulting from differing coefficients of expansion, power supplies that can be used to power one or more chiplets can be arranged on one or more modular power substrates (MPSs). The MPSs can accommodate lateral displacement between other elements that expand and contract, minimizing potential material strain. Recall that a unified control board (UCB) to which the MPSs can be coupled can be used to enhance the coupling of the MPSs to a back side of a wafer-scale integration interposer (WSII). The coupling is accomplished using a plurality of conductive connecting materials such as elastomer sheets. However, since the UCB and the MPSs can flex under compression, the MPSs can be stiffened based on a reinforcement structure at each gap in an isometric grid array. The modular power substrates enable back side power delivery for wafer-scale integration with an isometric grid array with compression pins.

A wafer-scale silicon interposer (WSII) is accessed. A front side of the WSII is bonded to a plurality of chiplets. The WSII includes a plurality of through-silicon vias (TSVs). A plurality of modular power substrates (MPSs) is inserted into an isometric grid array (IGA). A back side of the IGA includes a plurality of external compression pins. The plurality of MPSs is coupled to the plurality of chiplets. The coupling includes compressing, by one or more compression plates, one or more elastomer sheets between the plurality of MPSs and the plurality of TSVs. The compressing is based on the plurality of external compression pins. The plurality of MPSs is coupled to a plurality of DC-to-DC power converters. The coupling is based on a plurality of sockets. DC power is sent, by the plurality of DC-to-DC power converters, to the plurality of chiplets. The sending is based on the plurality of MPSs, the one or more elastomer sheets, and the plurality of TSVs.

The diagram 300 shows a modular power substrate (MPS). Elements such as one or more DC-to-DC power converters (which can be power supplies), connectors, etc. can be mounted to an MPS 310. The number of elements that can be mounted to the MPS can be based on the size, shape, and so on of the MPS. A plurality of MPSs can be used to deliver power to a plurality of chiplets. The MPSs can be based on a variety of substrate materials. In a usage example, one or more MPSs within the plurality of MPSs can include an organic substrate. An organic substrate can be based on one or more organic materials such as organic materials used to manufacture printed circuit boards. The organic substrate materials can include paper cores impregnated with phenolic resin, woven or unwoven glass cloth impregnated with epoxy or cyanate ester among others, natural fibers, etc. In a further usage example, one or more MPSs within the plurality of MPSs can include an inorganic substrate. An inorganic substrate can be based on a silicon glass with a coefficient of expansion similar to the WSII, etc.

An MPS can include a form factor. Recall that a plurality of chiplets can be bonded to a front side of a wafer-scale integration interposer (WSII). A plurality of MPSs can be based on a form factor mirroring one or more corresponding chiplets, within the plurality of chiplets, on the front side of the WSII. The plurality of MPSs is coupled to the plurality of chiplets via the back side of the WSII. The MPSs can be further coupled to a unified control board (UCB). Thus, the MPSs can be situated between the UCB and the WSII. As described above, the WSII and the UCB can have different coefficients of thermal expansion leading to different amounts of lateral displacement. The differing lateral displacements can be sufficient to fracture connections and/or introduce warpage into components which can lead to connection failures such as disconnected connectors or cracked C4s, damage due to physical strain, etc. The modularity of the MPSs can provide a flexible power delivery system to the chiplets which can accommodate different movements of the WSII and UCB due to thermal expansion. For example, an MPS at one side of the WSII can be decoupled from an MPS on the other side of the WSII, thus accommodating various movements across the WSII and UCB.

DC-to-DC power converters 320, which can be power supplies, can be coupled to the MPS. In the figure, two power converters are shown in a stack configuration. The MPS can include additional power converters attached to the MPS at additional positions across the MPS. While stacks of two power converters are shown at each position, a given position can include no power converters, one power converter, two power converters, etc. The number of power converters attached to the MPS can be based on the dimensions of the MPS, the dimensions of the power converters, a voltage or current required by the chiplets, coefficients of expansion, heat dissipation, etc. The MPS can include one or more power connectors 330. The power connectors can fit with a high voltage socket, a high-power socket, etc. from the UCB. The power connections can include compliant power connectors, where the compliant power connectors can maintain a reliable connection even under the lateral displacement of the MPS due to heating. The power connectors can include one or more of positive terminals, negative terminals, common terminals, and so on. The power connectors can include control terminals, data terminals, etc. The high voltage socket can accommodate lateral movement due to thermal expansion. The power connector can be located in the middle of the MPS, at the top of a stack of MPSs as shown in the diagram 300, or in another location.

The pressure which can engage the elastomer sheets at the back side of the WSII can be delivered by the MPS as the IGA compresses the MPSs into the back side of the WSII. As described previously, a compression force can be delivered by one or more compression plates, reinforcement crossbars within the IGA, and external compression pins extending from the back side of the IGA which can contact one of the compression plates. However, the MPS may not be completely planar, and the force applied at the middle of the MPS may not be enough to fully engage the elastomer sheets throughout the underside of the MPSs. To maintain planarity of the MPSs and to provide uniform compression force to engage the elastomer sheets at the back side of the WSII, stiffening techniques can be applied. Embodiments include stiffening the IGA, wherein the stiffening is based on a plurality of reinforcement crossbars within one or more open recesses within the IGA. Further reinforcement structures, such as a ring (not shown in the diagram 300), can be deposited on the MPS to stiffen the MPS. The stiffening of the MPS via reinforcement rings and/or crossbars can enhance planar compression of the elastomer sheets between the MPSs and the back side of the WSII. The reinforcement crossbars can come in contact with the MPSs to apply substantially equal pressure across each MPS within the plurality of MPSs. The reinforcement rings and/or crossbars can enable a compression force applied by the IGA to be distributed across each MPS. The compression force can then be transferred from each MPS to the elastomer sheets that couple the MPSs and the WSII.

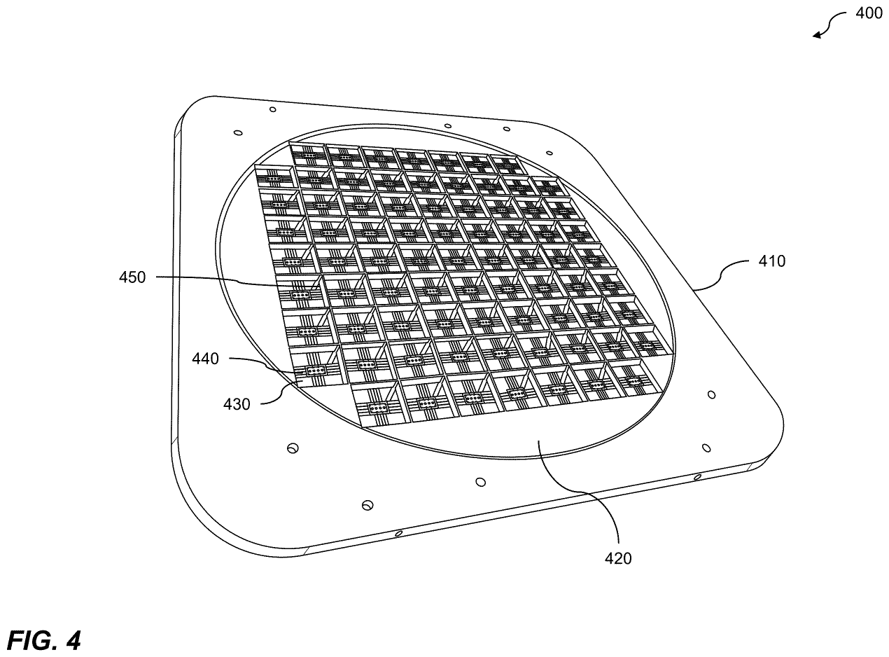

FIG. 4 is a top view of an isometric grid array (IGA). The IGA can include reinforcement structures such as reinforcement crossbars. The IGA can provide stiffening to a wafer-scale integration interposer (WSII). The WSII can include a plurality of chiplets that can be bonded to a front side of the WSII. The WSII further includes a plurality of through-silicon vias (TSVs). A plurality of modular power substrates (MPSs) can be inserted into an isometric grid array (IGA). A back side of the IGA includes a plurality of external compression pins. The plurality of MPSs is coupled to the plurality of chiplets. The coupling includes compressing, by one or more compression plates, one or more elastomer sheets between the plurality of MPSs and the plurality of TSVs. The compressing is based on the plurality of external compression pins.

Further, reinforcement structures associated with each recess within the IGA can apply an amount of compression to each MPS to ensure proper seating of connectors between the MPSs and the WSII. The walls of the open recesses within the IGA can be sufficiently thin to minimize consumption of WSII real estate. The walls of the IGA can further be strong enough to support and stiffen the WSII, thereby substantially reducing the risk of fracturing the WSII. Cracking or breaking of the WSII can result from the thinness to which the WSII was ground, polished, and so on in order to enhance fabrication of through-silicon vias (TSVs) associated with the WSII. The cracking or breaking can also result from the weight of the chiplets and the MPSs. The TSVs enable communication between the chiplets and the MPSs. The stiffening of the isometric grid array enables wafer-scale integration with an isometric grid array with compression pins.

The top view 400 illustrates a top view of an isometric grid array (IGA) 410. The IGA can include a variety of materials such as various alloys of steel, aluminum, and so on. In a usage example, the IGA can comprise copper. The IGA can include a recess such as a circular recess 420. The recess 420 can include a variety of sizes, where the sizes can correspond to a size of a wafer. The wafer can include a 300 mm wafer, a 200 mm wafer, and the like. The recess can accommodate the WSII. The IGA can further include open recesses such as open recess 430. Recall that the MPSs can be inserted into the IGA. The sizes of the open recesses can be chosen to accommodate the MPSs and/or a lateral displacement of the MPSs that can result from heating of the MPSs during operation. The IGA can comprise a grid, such as shown in top view 400. The IGA grid can include square open recesses as shown, or further shapes appropriate to a form factor of the MPSs. The further shapes can include rectangles, circles, ovals, a honeycomb, etc.

The IGA can stiffen the WSII as discussed and can provide other benefits to the WSII. The stiffening can be accomplished using reinforcement structures. Embodiments include stiffening the IGA, wherein the stiffening is based on a plurality of reinforcement crossbars within one or more open recesses within the IGA. An example reinforcement crossbar structure is shown 440. The reinforcement structure is discussed further below. In embodiments, the IGA maintains a coplanarity of the WSII. The coplanarity of the WSII can counteract sagging or warping of the WSII due to the weight of bonded and/or attached elements, thermal expansion of elements such as chiplets and MPSs that are bonded to or attached to the WSII, and so on. As shown in top view 400, a back side of the IGA includes a plurality of external compression pins. An example external compression pin is shown 450. In embodiments, the plurality of reinforcement crossbars and the plurality of external compression pins enable planar compression of the one or more elastomer sheets. Discussed previously, planar compression of one or more elastomer sheets can enable reliable connections between the MPSs and the TSVs in order to send DC power from the plurality of DC-to-DC converters associated with the MPSs, via the TSVs, to the plurality of chiplets. In embodiments, the plurality of reinforcement crossbars and the plurality of external compression pins enable planar compression of the one or more elastomer sheets.

Recall that a first compression plate can exert force on a first cold plate which can be mounted to the plurality of chiplets bonded to the front side of the WSII. Embodiments include mounting a first cold plate to the plurality of chiplets. The WSII can be inserted into the circular recess of the IGA where it can come into contact with elastomer sheets on top of MPSs that have been inserted into the IGA. The external compression pins of the IGA can be inserted through the UCB and through a second cold plate to contact a second compression plate.

In embodiments, the plurality of DC-to-DC power converters comprise a unified control board (UCB). In some embodiments, the clamping includes inserting, through a plurality of holes within the UCB, the plurality of external compression pins. Other embodiments include mounting a second cold plate to the plurality of DC-to-DC power converters. In embodiments, the clamping includes inserting, through a plurality of holes within the second cold plate, the plurality of external compression pins. The first compression plate and the second compression plate can exert pressure based on one or more clamps. Since the external compression pins can be distributed around the IGA and contact the second compression plate, the external compression pins can exert the pressure on the MPSs in a planar fashion.

Recall that the MPSs can be based on a form factor. In a usage example, each MPS within the plurality of MPSs can be based on a form factor mirroring one or more corresponding chiplets, within the plurality of chiplets, on the front side of the WSII. The form factor associated with the MPSs can also be applied to the IGA. In a usage example, each open recess within the plurality of open recesses within the IGA matches a form factor of a corresponding MPS in the plurality of MPSs. Recall that the MPSs are coupled to the back side of the WSII through the plurality of open recesses within the IGA. In embodiments, the IGA contacts the back side of the WSII between each MPS in the plurality of MPSs. In a usage example, an MPS can be inserted into one or more of the open recesses within the IGA. The back of the MPSs can then be coupled to the back side of the WSII via one or more conductive connecting materials such as elastomer sheets. If fewer than a full complement of MPSs have been inserted to the back side of the WSII, then one or more of the open recesses within the IGA can remain open.

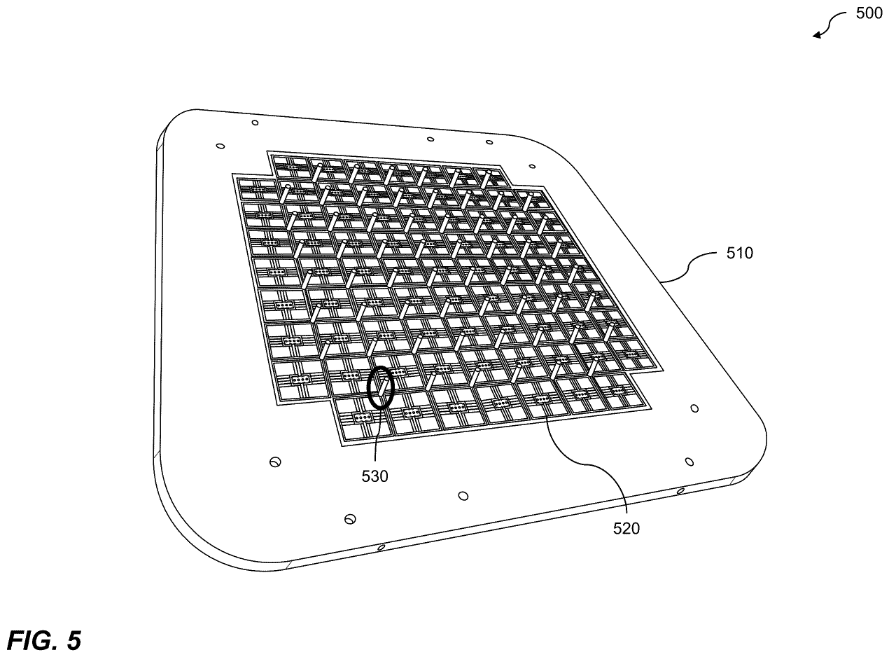

FIG. 5 is a bottom view of an isometric grid array (IGA) 500. Recall that a plurality of modular power substrates (MPSs) can be coupled to a plurality of chiplets. The MPSs can also be coupled to a plurality of DC-to-DC converters. The DC-to-DC converters can be used to send power to the plurality of chiplets, based on the MPSs. The sending the DC power can be further based on the plurality of MPSs, one or more elastomer sheets, and a plurality of through-silicon vias (TSVs). Compression can be used to couple the plurality of MPSs to the plurality of chiplets. The compression can be accomplished by using one or more compression plates. The compression can include clamping based on one or more clamps. However, the WSII can deflected under compression, so the IGA can be used to support the WSII to protect the WSII from fracturing under compression. Further, in embodiments, the IGA can maintain a coplanarity of the WSII. The coplanarity can be accomplished using reinforcement structures associated with the IGA. To attain coplanarity, the IGA can include reinforcement structures such as reinforcement crossbars. The reinforcement crossbars associated with the IGA can be used to provide stiffening to a wafer-scale integration interposer (WSII). In additional to the reinforcement crossbars, the back side of the IGA includes a plurality of external compression pins. The plurality of reinforcement crossbars and the plurality of external compression pins maintain coplanarity of the WSII. Coplanarity of the WSII enables back side power delivery for wafer-scale integration with an isometric grid array with compression pins.

The bottom view 500 shows a back side or bottom view of an isometric grid array (IGA) 510. The IGA can include a variety of materials such as various alloys of steel, aluminum, and so on. The IGA can include one or more open recesses. The open recesses can enable attaching a plurality of modular power substrates (MPSs) to the back side of the WSII.

The sizes of the open recesses can accommodate the MPSs and/or a lateral displacement of the MPSs that can result from heating of the MPSs during operation. The IGA can comprise a grid. The IGA grid can include square open recesses as shown, or further shapes appropriate to a form factor of the MPSs. The further shapes can include rectangles, circles, ovals, a honeycomb, etc. The IGA can stiffen the WSII as discussed, can remove a portion of heat generated by the MPSs, and so on. The stiffening can be accomplished using reinforcement structures. The bottom view 500 includes stiffening the IGA, wherein the stiffening is based on a plurality of reinforcement crossbars 520 within one or more open recesses within the IGA.

Discussed above, the IGA can maintain a coplanarity of the WSII. The coplanarity of the WSII can counteract sagging or warping of the WSII attributable to the weight of bonded and attached elements such as chiplets and MPSs. The sagging or the warping can also result from any thermal expansion of elements that can include the chiplets bonded to and the MPSs coupled to the WSII. A back side of the IGA can include a plurality of external compression pins. In the bottom view 500, an example external compression pin is shown 530. As previously noted, in embodiments, the plurality of reinforcement crossbars and the plurality of external compression pins enable planar compression of the one or more elastomer sheets. The planar compression of the one or more elastomer sheets is essential for reliable connections between the MPSs, and the MPSs and the TSVs, in order to send DC power from the plurality of DC-to-DC converters associated with the MPSs, via the TSVs, to the plurality of chiplets. The plurality of reinforcement crossbars and the plurality of external compression pins enable planar compression of the one or more elastomer sheets.

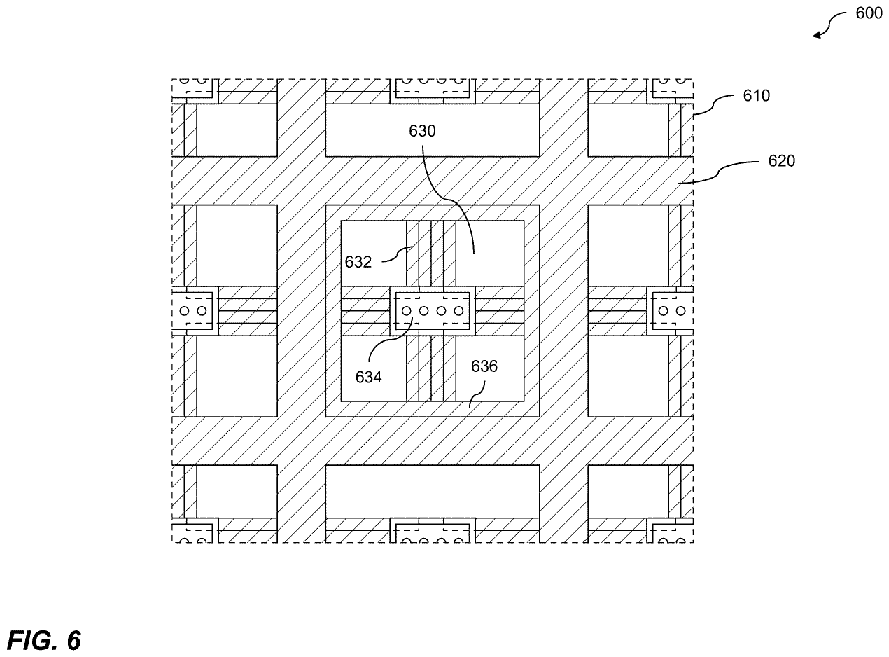

FIG. 6 is a diagram of reinforcement crossbars. The reinforcement crossbars can be used to provide support for an isometric grid array (IGA). The crossbars can be used in conjunction with other reinforcement structures such as reinforcement rings on the MPSs as described previously. Discussed previously and throughout, a plurality of modular power substrates (MPSs) can be coupled to a back side of a WSII. The MPSs provide DC power to chiplets bonded to a front side of the WSII. The plurality of MPSs is coupled to a back side of the WSII based on one or more elastomer sheets. The elastomer sheets provide coupling, which can include adhering, of the MPSs to the WSII, and further provide conduction paths between contacts or pads associated with the MPSs and contacts or pads associated with the WSII. An isometric grid array (IGA) can be used to compress each conductive connecting material to enable the coupling. Further embodiments include stiffening the IGA, wherein the stiffening is based on a plurality of reinforcement structures such as reinforcement crossbars and compression pins. The stiffening helps to protect the integrity of the WSII. The plurality of reinforcement structures can help to equalize the compressing of the MPSs across the WSII. In embodiments, the plurality of reinforcement crossbars and the plurality of external compression pins enable planar compression of the one or more elastomer sheets. The coupling enables backside power delivery for wafer-scale integration with an isometric grid array with compression pins.

The FIG. 600 shows a diagram of a reinforcement structure. A detailed view of a portion of an isometric grid array (IGA) is shown 610 as a dashed line. The IGA can include recesses, where the recesses can include square recesses, rectangular recesses, oval recesses, honeycomb recesses, and so on. In embodiments, the IGA comprises a grid 620. The grid can comprise a variety of materials such as alloys of steel, aluminum, titanium, and so on. In a usage example, the grid material can include copper. Embodiments further include stiffening the IGA, wherein the stiffening is based on a plurality of reinforcement crossbars within one or more open recesses within the IGA. An example recess within the IGA is shown 630. One or more reinforcement structures can be formed within the open recess. The reinforcement structures can include reinforcement crossbars, reinforcement rings, and so on. An example reinforcement structure is shown in recess 630. The reinforcement structure can be deposited in the IGA, glued to the IGA, and so on. A reinforcement structure can be included in any recess within the IGA. The reinforcement structure can include crossmembers such as crossmember 632. The crossmembers can fix the reinforcement structure within a recess within the IGA. A centerpiece 634 can be at the intersection of the crossmembers within the reinforcement structure. The centerpiece can include a plurality of holes to accommodate pins associated with a connector. The shape of the crossmembers and centerpiece can correspond to shapes of structures such as power modules, sockets, etc. on the MPSs, such that the MPSs can be inserted into the IGA. The connector can be coupled to an MPS. The centerpiece can apply pressure to the connector, thereby enabling a more reliable connection. In a usage example, an MPS can be inserted into the plane of illustration 600. The power converters on the top of the MPS can slide through the grid structure while the power socket on the top of the MPS can mate with the centerpiece 634. The reinforcement can further include an outer reinforcement member 636. The outer reinforcement member can press the edges of the MPS into the WSII which can be coupled to the backside of the MPS.

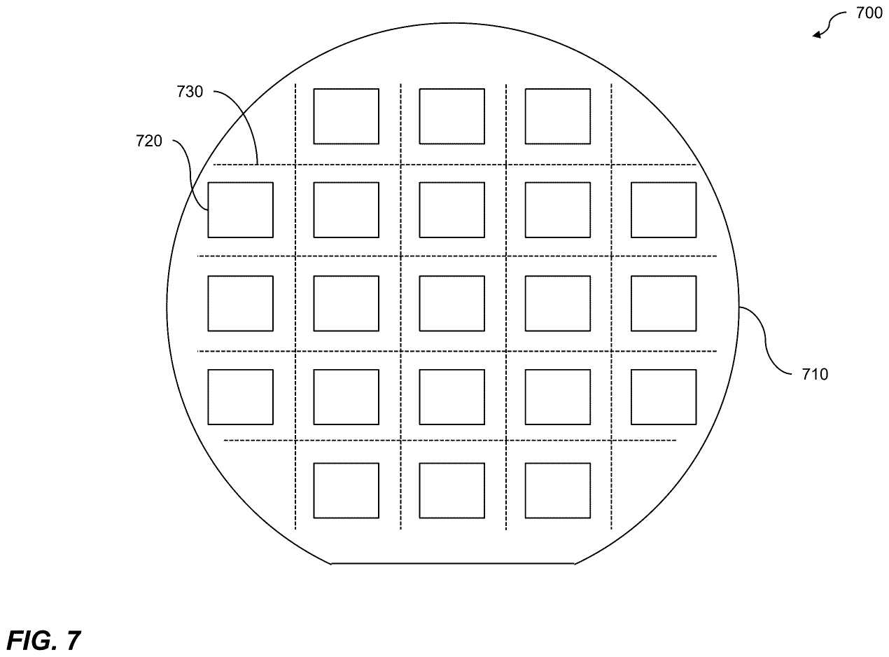

FIG. 7 illustrates a wafer with multiple die. A semiconductor wafer such as a silicon wafer is used in the fabrication of electronic circuits. Other semiconductor materials such as germanium, silicon carbide, indium phosphide, gallium nitride, etc. can also be used. The wafers that are used are obtained in various sizes. One common wafer size includes a 300 mm silicon wafer. Integrated circuits or “chips” can be fabricated on the surface of the wafer by applying, removing, etc. various layers. The layers are applied to the wafer using techniques that can include diffusion, deposition, etching, planarization, and so on. The numbers of layers applied to the wafer can include dozens of layers, hundreds of layers, and so on. The layers can include active areas, polysilicon, metal, contacts, vias, and so on. The circuits are called “die” during fabrication. The die can include a plurality of similar circuits or can include two or more different circuits or “projects.” The similar circuits and the different projects can include processors, memories, mixed-signal chips, and so on. The multiple die that can be fabricated on the semiconductor wafer can include accelerators for artificial intelligence and machine learning. The multiple die can be used to enable back side power delivery for wafer-scale integration with an isometric grid array with compression pins. Reinforcement structures associated with an isometric grid array (IGA) can be used to stiffen elements such as modular power substrates (MPSs). The reinforcement structures can be glued, deposited, or otherwise applied to each opening associated with the IGA. The reinforcement structures maintain a coplanarity of each MPS in the plurality of MPSs.

The FIG. 700 shows a wafer with multiple die. A wafer can be based on a monocrystalline semiconductor material. The semiconductor material can include a group IV material such as silicon, a group III-V material such as gallium arsenide, and so on. The die on the wafer shown are substantially similar in size. However, the die can be substantially different in size. A system can depend on a certain number of functional die. For instance, an artificial accelerator used for training a large language model (LLM) to be executed on a neural network (NN) can require a large number of functional die. The die can be comprised of AI accelerators, ML accelerators, and so on. Since a wafer will contain defects randomly distributed across the wafer, some of the die fabricated on the wafer will be affected by the wafer defects and will not function properly. By fabricating multiples of the die, the probability of fabricating at least one functioning chip increases. Further, because the presence or absence of circuits or die on the wafer can influence successful fabrication of a given die, a wafer can be “covered” with circuits for fabrication. Because of the shape of the wafer, which is typically round with at least one flat edge to aid alignment, some of the circuits may not be fully contained within the boundaries of the wafer. The resulting “partial” circuits or die will not function fully or at all. In some cases, the partial die may be usable in other applications.

A wafer is shown 710. The wafer can include multiple die such as die 720. The multiple die can be replicas of the same chip. In some cases, the multiple die can be different die, such as SRAM die. The die on the wafer can all be fabricated using the same fabrication technology. If any die requires different fabrication technologies, then that die must be fabricated on a different wafer. While 21 die are shown on the wafer, in practice any number of die can be present. The number of die will depend on the size of the wafer and the size of the die. When fabrication steps, of which there can be many, are completed, the die can be separated. The figure shows a plurality of dashed lines such as line 730. The dashed lines represent scribe lines or kerf associated with the wafer. A saw, a laser, etc. is used to slice the wafer into liberated, individual die. Since the saw or other cutting device has a finite width, some wafer material is lost due to the width of the saw or cutting device. As a result, any structures such as test structures used to track processing steps during fabrication are lost.

While multiple die are shown in the diagram, the desire to further push the size of individual die has continued at a rapid pace. As one reference point, a packaged processor chip that is larger than 35 mm on a side has become common. However, as die on a wafer become larger, the risk of individual die being impacted by defects in the wafer, or defects associated with any of the many fabrication steps, increases. How, then, could one produce even larger chips? One suggestion that has long been proposed is to use the “entire” wafer to form a single large chip or “super chip.” In addition to producing the one chip on the wafer, packaging could potentially be reduced since the packaging would involve the one chip instead of a typical suite of chips, where each chip requires its own packaging. Wafer scale integration or WSI has been proposed as particularly well suited to applications that demand extensive data processing. Examples proposed that could benefit from WSI have included computer architectures appropriate for massively parallel supercomputers, and computationally intensive applications such as machine learning and deep learning. However, successful fabrication of a single chip across an entire wafer is an extremely difficult undertaking. Noted above, the widespread and random distribution of defects and other variations such as warpage across a wafer render the ability to build one “super-circuit” elusive. Also, circuit redundancy becomes a major design issue. Not only are redundant circuits that can be switched in to replace defective circuits necessary, but the locations of the redundant circuits are also critical. Note that the redundant circuits must be connected in place of the defective circuits, and that wiring on an integrated circuit is extremely expensive in terms of real estate. As a result, the placement of the redundant circuits must be carefully considered to conserve wafer real estate and to reduce wiring complexity.

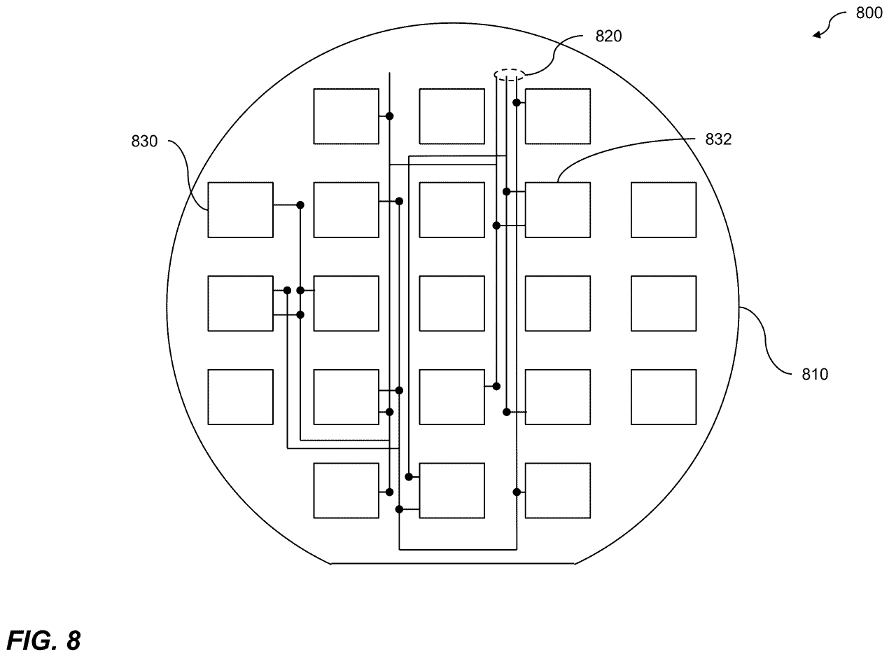

FIG. 8 illustrates inter-die interconnect for wafer-scale integration. Discussed previously and throughout, the demand for ever larger integrated circuits that can meet increasingly intensive processing demands has been stymied by the difficulty of producing large, single chips. One of the fundamental difficulties of producing a large chip, such as a wafer-sized chip, is that defects are randomly distributed across a wafer on which the large chip would be produced. Further, defects, such as disconnects in wiring, variations in oxide (insulator) thicknesses, open-circuit contacts, varying doping profiles, and so on, can be introduced during the fabrication process. One possible approach to “wafer-scale” integration is to continue to fabricate circuits on the wafer. Then, instead of cutting the wafer to access the individual dies, the wafer remains whole. By adopting an approach such as this one, the kerf, previously lost to the cutting of the wafer into the individual die, can be used for interconnect channels. Recall that interconnect on a wafer consumes wafer real estate that cannot otherwise be used for circuitry. By capturing the real estate previously lost to the kerf, additional wafer real estate that can be used for interconnect is captured. The interconnect in the kerf is particularly appropriate for long-haul connections, such as connections between individual die on the wafer. Since the wafer can be thinned during fabrication to enable vias, called through-silicon vias, to provide connections between a front side of the wafer and a back side of the wafer, the wafer can be reinforced. Back side power delivery for wafer-scale integration with an isometric grid array with compression pins is enabled by inter-die interconnection.

The FIG. 800 illustrates use of wafer real estate, otherwise lost to scribe lines or kerf for inter-die interconnect, for wafer-scale integration. A wafer 810 is shown on which multiple die, or chips, are distributed. The die are fabricated together on the wafer. That is, each of the die on the wafer is fabricated based on the same processing steps. Since the individual die will not be separated from the wafer using a cutting technique, the kerf area of the wafer can be used for interconnect. Other areas of the die can also be used for interconnect. The interconnect 820 can be placed in wiring channels or routes, where the wiring channels are realized in what would formerly have been the kerf. The wiring channels include wafer real estate in which interconnecting wire can be placed. The interconnect can be fabricated while the various die on the wafer are fabricated. The interconnect can include a plurality of wiring layers. The various layers can be interconnected using contacts, vias, and so on. In the figure, a few example interconnecting runs are shown. The various die on the wafer can make connections to the wiring channels. In the figure, die 830 can use the wiring channels to connect to die 832.

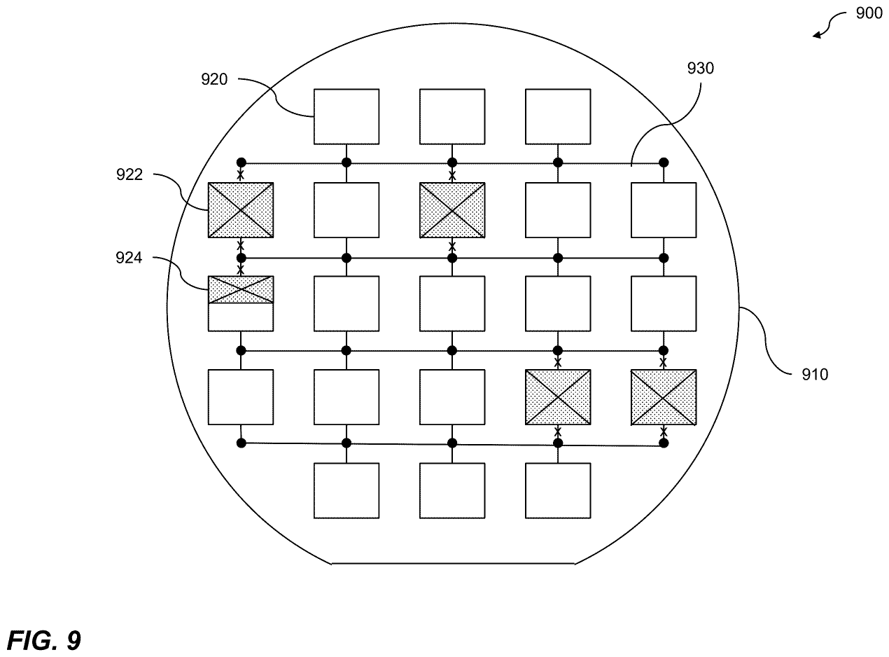

FIG. 9 shows inter-die interconnect and redundancy for wafer-scale integration. Building on the previous discussions of techniques including fabricating redundant die on a wafer and of using the kerf for interconnect, a technique for wafer-scale integration (WSI) can be based on fabricating redundant die on the wafer, and selecting the working die for use by a system based on WSI. Working die can be selected while non-working die, partial die, and other substandard die can be electrically ejected from the system by deselecting the die. The deselecting can include disabling wired connections to the unused die, physically “blowing” connections to the unused die (e.g., a fuse), and so on. The remaining functioning die can be interconnected using inter-die interconnect to form a system on the wafer. The system on the wafer can achieve the desired objective of wafer-scale integration. Power, data, control signals, and so on can be provided to the selected, working die. Due to the size of the wafer on which the interconnected die are fabricated, the wafer can be subject to warping, cracking, breakage, and so on. The wafer can be supported or stiffened such that risks of damage to the wafer and the die on the wafer can be minimized. Further, connections between the wafer and elements such as power supplies, DC-to-DC converters, controllers, and so on can be established using selectively conducting elastomer sheets. Inter-die interconnect and redundancy to support back side power delivery for wafer-scale integration with an isometric grid array with compression pins are enabled with an isometric grid array.

The FIG. 900 shows redundant die and inter-die interconnect. A wafer is shown 910. The wafer is populated with multiple die such as die 920. A number of the die shown can be redundant. Some of the redundant die will include defects, can be incomplete, can miss specifications, or can otherwise fail. The defects can be associated with the wafer on which the die are fabricated, associated with one or more processing steps for fabricating the die, and so on. This can result in die that are not operational, such as die 922. Recall that die can be fabricated on the wafer in order to ease some fabrication complexities, and that some of the added die can include partial die such as die 924. The failed die and the partial die can be excluded from a system formed by wafer-scale integration (WSI). In some cases, a die such as 924 can be partially functioning. The portion of the die that is functioning can be included in the WSI, while the portion of the die that is not functioning can be excluded. The functioning die can be inter-connected using inter-die interconnect 930. The inter-die interconnect can include multi-layer interconnect. The inter-die interconnect can be placed between the die associated with the multiple projects. Functioning die can be connected to the inter-die interconnect, while non-functioning die can be disconnected from the inter-die interconnect.

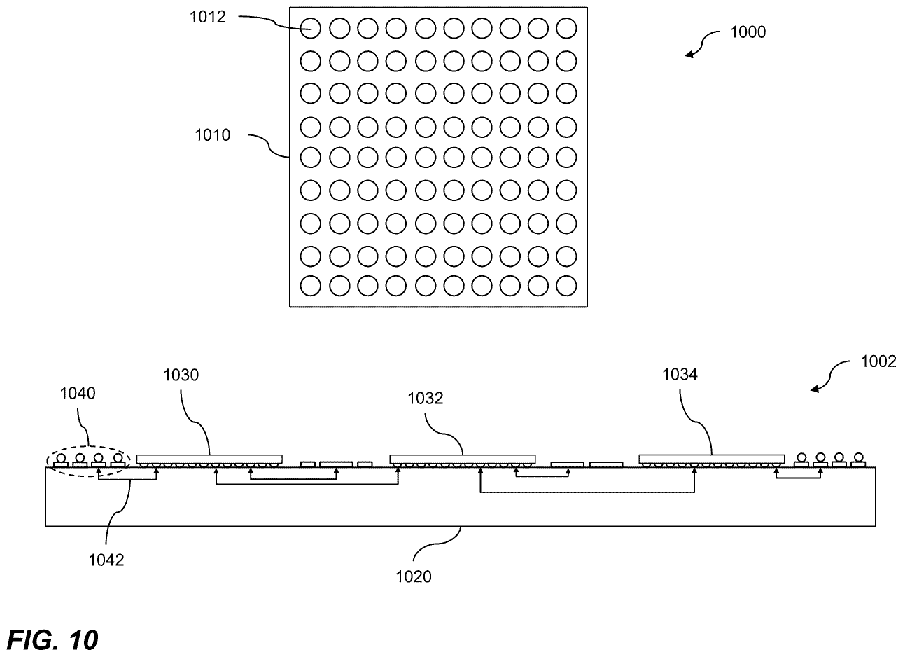

FIG. 10 illustrates a flip-chip and interposer with flip-chips for wafer-scale integration. One technique that can be used to approach the benefits of wafer-scale integration is to attach more than one chip to a common substrate or interposer. The substrate can include a wafer, a carrier, a circuit board, and so on. To accomplish such a technique, all interconnections to a circuit or chip, including data connections, control and signal connections, power connections, and so on, can be made at the top layer of the chip. The connections at the top of the chip replace the traditional placement of pads at the periphery of the chip. To connect the top connections of the chip to the interposer, solder balls are placed on the top connections and the chip is inverted or “flipped.” The solder balls, when melted, can connect the top connections of the chip to corresponding connections or pads on the interposer. Further chips can be similarly flipped and connected to additional corresponding connections on the interposer. One challenge to the flip-chip technique is providing power to the chips. The power can be provided using back side power delivery for wafer-scale integration with modular power substrates (MPSs). A further challenge to the flip-chip technique is that the aggregate weight of the flipped chips can be sufficient to pose a risk to the delicate wafer or interposer. The wafer can be stiffened in order to protect it from the weight of the flipped chips. The stiffening can be accomplished using an isometric grid array (IGA). The IGA can include a plurality of reinforcement structures. The plurality of reinforcement structures enables planar compression of each elastomer sheet within a plurality of elastomer sheets. The elastomer sheets enable attachment of the plurality of MPSs to a back side of a wafer-scale silicon interposer (WSII). The back-side power delivery for wafer-scale integration is enabled with an isometric grid array with compression pins.

The FIG. 1000 includes an example flip-chip. Discussed previously, the flip-chip 1010 differs from a traditional chip in that the connections to the flip-chip are made at the top of the chip rather than to pads located at the periphery of the chip. A top view of a flip-chip is shown. The top can include pads that can be connected to corresponding pads on a multi-chip module, a circuit board, an interposer, and so on. An example contact or pad 1012 is shown. Multiple pads can be distributed across the top of the flip-chip. The pads can be oriented to correspond with receiving pads on the interposer. An array of pads is shown. In a usage example, a subset of pads can be required to connect the flip-chip to the interposer. Thus, required pads are present at the top of the flip-chip, while the unused pads can be omitted from the top of the flip-chip.

The illustration 1002 shows an example interposer. As discussed previously, the interposer 1020 can include a wafer, a carrier, a circuit board, and so on. One or more flip-chips can be bonded to the interposer. In the figure, the flip-chips can include a first flip-chip 1030, a second flip-chip 1032, a third flip-chip 1034, and so on. While three flip-chips are shown, other numbers of flip-chips can be bonded to the interposer. In a usage example, the flip-chips can be bonded to the interposer in a grid pattern. In addition to serving as a placement location for the flip-chips, the interposer can provide interconnect. The interconnect can be used to provide signals such as control signals, data, and so on to the flip-chips. The interconnect can further provide power to the flip-chips. Depending on the interposer used to receive the flip-chips, the interposer can include one or more layers of interconnect. The interconnect can include interconnect at a top surface of the interposer such as top surface interconnect 1040. The interposer can further include additional layers of interconnect. The additional layers of interconnect can be fabricated on the interposer. The additional layers of interconnect can be isolated from each other using an insulating layer between the conducting interconnect layers. An example “lower layer” connection 1042 is shown.

The use of flip-chips bonded to an interposer can enable multichip module (MCM) techniques. A multichip module can refer to a substrate, carrier, circuit board, interposer, etc. onto which multiple ICs can be placed. The multiple ICs can be bonded to the interposer, and the multiple ICs can be wired together using interconnect provided by the interposer. The interconnect associated with the interposer can provide power, control signals, and data between and among the ICs that are bonded to the interposer. The power can be provided using modular power techniques. Depending on the particular type of MCM, the interposer can further include discrete components such as discrete resistors, discrete capacitors, discrete inductors, discrete diodes, etc. The interposer further includes wiring for interconnecting ICs and the discrete components, if any. The MCM can be packaged and used as if it were a single IC on a board such as a circuit board within a system. MCMs have also been referenced as heterogeneous integration circuits and hybrid integrated circuits. A principal advantage of using MCMs is that multiple electronic components can be enclosed in a single “chip,” thereby improving modularity of a system design. Also, the use of MCMs can improve IC yields over ICs produced using monolithic IC design methodologies.

There can be several varieties of MCMs, where the MCM varieties are typically differentiated by size, complexity, design methodology, and so on. At one end of the complexity scale, an MCM can include standard off-the-shelf ICs. The ICs can be bonded to a circuit board such as a printed circuit board and can be used in place of an existing chip or package of chips. The printed circuit board can be designed to match the size and pin-out of the existing chip or package of chips. An MCM can also be a complex element. The complex MCM can be based on one or more fully customized IC packages. The fully customized IC packages can be used to integrate multiple IC dies (e.g., unpackaged ICs) onto a substrate that provides interconnection among the dies. Because of the wiring requirements of the multiple IC dies, the substrate typically includes high density interconnection (HDI). The substrates that are used for the MCM can include thin films for interconnects (wires) and dielectrics (insulators); thick films that enable more than one layer of interconnect and ceramics; and substrates that include laminates based on organics or plastics. The MCM based on thin films of interconnects and dielectrics can result in the highest circuit densities.

The MCM design concepts described previously suggest promising leads for implementing wafer-scale integration ICs. Multiple circuit dies could be fabricated within the same wafer. The wafer could further include built-in self-test (BIST), circuit redundancy to provide spare parts, and “self-rerouting. ” The self-rerouting can “reroute” around defective, incomplete, or failed elements and can wire in known good spare parts. In order to enable such capabilities, a significant number of interconnect layers would be required for WSI. Interconnect layer counts of approximately ten layers have been predicted. In order to implement WSI in a cost-effective manner, several techniques have been proposed, such as using an artificial neural network to develop a programmable topology, using a multichip-scale package, and so on.

Another technique that is being developed to enable wafer scale integration is based on the use of a silicon interposer, as discussed above. The interposer can further include an interposer based on other materials such as glass. The silicon interposer, which can be a wafer, can be used to provide interconnections among a wide variety of components. The components include integrated circuits (chips), chiplets, power supplies, power converters, discrete electrical components, and so on. The interposer provides connection points that can be used to mechanically and electrically mount the chips, chiplets, etc. The interposer can be formed from inorganic materials such as glass or silicon, or organic materials such as those used to manufacture printed circuit boards. The electrical connections can be set to a pitch to simplify the attaching of the electrical elements. The electrical connections can be based on standardized manufacturing techniques such as using solder balls, micro-bumps, controlled collapse chip connection (C4) bumps, and/or electroplated bumps. The bumps on a chip are produced on the “top” side of a wafer (e.g., the non-substrate side) as a final processing step for the wafer. To mount the chips to the interposer, the chips are “flipped” using a flip-chip technique. The bumps at the top of the chips connect to pads on the interposer. The interposer can enable connections from the flip-chip to a standard connection arrangement such as a grid. The interposer can further provide one or more layers of interconnect according to the process used to manufacture the wafer. Thus, higher densities, higher bandwidth, and faster speeds can be achieved. The layers of interconnect are used to provide power and ground, control signals and data, and so on.

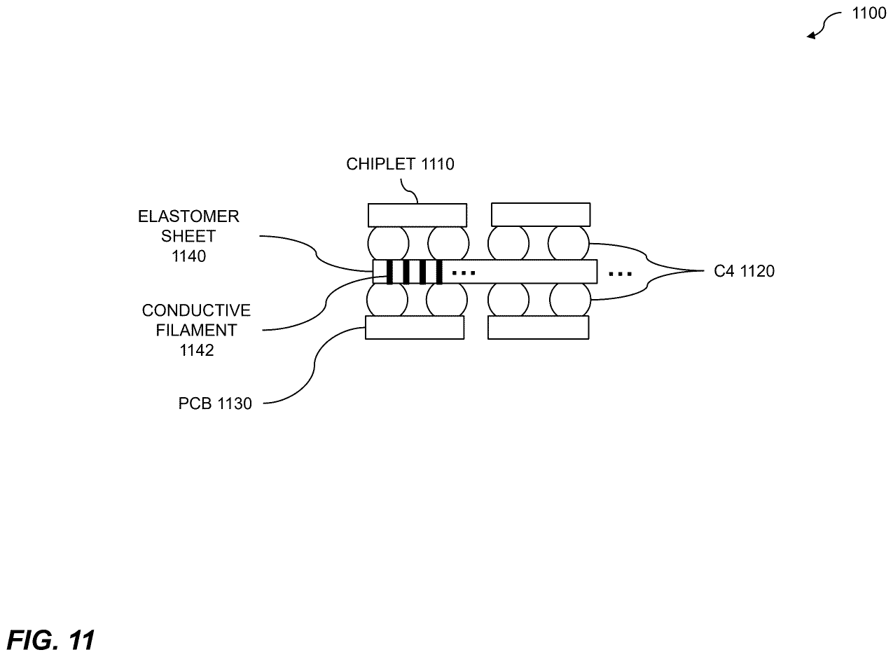

FIG. 11 is an example of an elastomer sheet. An elastomer sheet can include conduction paths between a top side of the elastomer sheet and a bottom side of the elastomer sheet. Conducting paths accessible on a top side of the elastomer sheet that are coupled to contacts, solder balls, microbumps, C4s, ball grid arrays (BGAs), and so on of an electronic element such as a modular power substrate (MPS) enable electrical connections to contacts, solder balls, etc. of a substrate such as a wafer-scale integration interposer (WSII). Discussed previously and throughout, a plurality of modular power substrates (MPSs) is coupled to a back side of a wafer-scale integration interposer (WSII). The plurality of conductive connecting materials attaches the plurality of MPSs to the WSII while further providing conduction paths between pads, contacts, terminals, etc. associated with each MPS and corresponding pads, contacts, terminals, etc. associated with the WSII. The conductive connecting materials include elastomer sheets. The attaching can include adhering, where the conductive connecting materials includes an adhesive. The coupling based on the plurality of conductive connecting materials enables back side power delivery for wafer-scale integration with an isometric grid array with compression pins.

The example 1100 shows a cross-section that includes chiplets, contacts, an elastomer sheet, and a printed circuit board (PCB). As shown, the elastomer sheet is used to couple at least one chiplet to a printed circuit board (PCB). The elastomer sheet can be used in many other implementations, such as coupling a back side of the aforementioned WSII to a plurality of MPSs using similar techniques. The figure shows a chip, or chiplet, 1110. While one chip is discussed, in a usage example, a plurality of chips such as chiplets can be included. The chiplet can include a processor chiplet, a multiprocessor chiplet, an AI accelerator chiplet, a switching chiplet, a controller chiplet, an I/O chiplet, and so on. The chiplet can include a memory such as a cache memory, SRAM, DRAM, high-bandwidth memory (HBM), etc. Contact to the chip can be accomplished using micro-bumps, controlled collapse chip connections (C4s), and the like. Examples of C4 connections are shown 1120. The chiplets can be coupled to a printed circuit board (PCB) 1130. More than one circuit board can be included. The circuit board can include a module. The printed circuit board can include an interposer, a wafer-scale integration interposer (WSII), a unified control board (UCB), and the like. The printed circuit board can include a plurality of contacts. The contacts on the PCB can correspond to contacts associated with one or more chiplets. The contacts on the PCB can include C4 connections 1120.

One or more elastomer sheets 1140 can be used to couple one or more chiplets to the PCB. The one or more elastomer sheets can include a variety of materials, configurations, and so on. In some embodiments, a single elastomer sheet can be used. An elastomer sheet can comprise conductive filaments 1142. The conductive filaments can include brass, silver, gold, etc., embedded in a sheet of silicone rubber or another suitable material. In the illustration 1100, the conducive filaments can be distributed throughout the elastomer sheet and can provide conductive paths between a front side of the elastomer sheet and a back side of the elastomer sheet. The distribution of the conducting filaments throughout the elastomer sheet can be based on a pitch. The pitch can be designed to match a connector array, such as a ball grid array (BGA) of the MPS. Thus, the elastomer sheet may not need any activation in order to form one or more conductive paths. Instead, some of the filaments will make contact with connections such as the C4s to the chiplet and to the PCB, while other filaments will not make contact. Thus, contacted filaments form connections between the chiplets and the PCBs, while other filaments remain unused. The elastomer sheet can be held in place with a compression force, such as described above. An adhesive backing can be added to the elastomer sheet. Thus, the elastomer sheet can accomplish adhesion of the one or more chips to the one or more PCBs. The elastomer sheet can provide conduction paths between the one or more chips and the one or more PCBs.

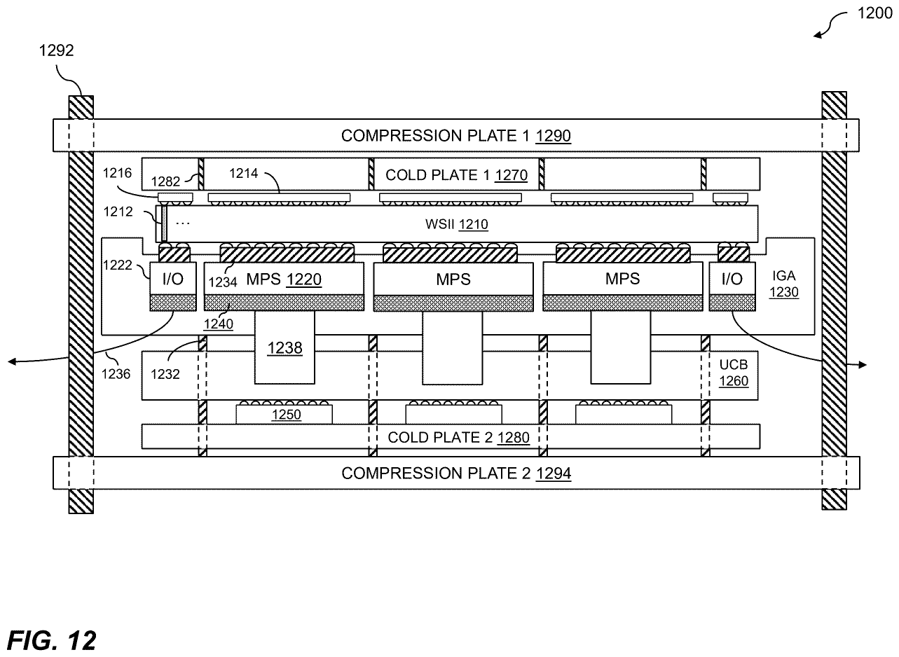

FIG. 12 is a cross-section of an apparatus for back side power delivery for wafer-scale integration with an isometric grid array with compression pins. Power such as DC power can be sent by a universal control board (UCB) to a plurality of chiplets. The sending can be accomplished using a plurality of DC-to-DC converters, a plurality of modular power substrates (MPSs), and a plurality of through-silicon vias (TSVs). The plurality of chiplets can be bonded to a front side of a wafer-scale integration interposer (WSII). The plurality of MPSs can be coupled to a backside of the WSII based on one or more elastomer sheets. The elastomer sheets can further provide configurable or preconfigured conduction paths between the MPSs and the WSII. The preconfigured conduction paths can include filaments, placed in a grid pattern, which enable connections between a front side of the elastomer sheet and a back side of the elastomer sheet. The MPSs can be coupled to the UCB based on a plurality of high-power sockets. The UCB can further include a plurality of DC-to-DC power converters. The attaching further includes compressing, by an isometric grid array (IGA). The IGA compresses each elastomer sheet. The IGA can include one or more external compression pins which can contact a compression plate to deliver the compression. The IGA can be stiffened based on a plurality of reinforcements. The stiffening can accomplish one or more goals associated with the apparatus. The stiffening can enable planar compression of the elastomer sheet. The planar compression can be based on one or more clamps. The planar compression can enable reliable coupling of conduction paths through the elastomer sheet to contacts, pads, etc. associated with the MPSs and the WSII.

An apparatus for power delivery is disclosed comprising: a wafer-scale integration interposer (WSII), wherein a front side of the WSII is bonded to a plurality of chiplets, wherein the WSII includes a plurality of through-silicon vias (TSVs); a plurality of modular power substrates (MPSs), wherein the plurality of MPSs is inserted into an isometric grid array (IGA), wherein a back side of the IGA includes a plurality of external compression pins; one or more elastomer sheets, wherein the one or more elastomer sheets are compressed between one or more MPSs in the plurality of MPSs and one or more TSVs within the plurality of TSVs, by one or more compression plates and the plurality external compression pins; and a plurality of DC-to-DC power converters, wherein the plurality of DC-to-DC power converters is coupled the plurality of MPSs via a plurality of sockets.

The apparatus 1200 includes a wafer-scale integration interposer (WSII) 1210, wherein a front side of the WSII is bonded to a plurality of chiplets, wherein the WSII includes a plurality of through-silicon vias (TSVs). The WSII can include inorganic materials or organic materials. In a usage example, the interposer can include a silicon interposer or a glass interposer. Micro-bumps, C4s, and the like can be used to mount the one or more chiplets to the front side of the WSII. Communications between the chiplets can be accomplished within metal layers of the interposer, thereby reducing latency and parasitics such as resistance, capacitance, and inductance, enabling improvement of signal integrity and/or bandwidth, etc. The reductions and improvements result from the opportunity for many more wires to be established within the WSII compared to what would have been possible with a typical packaging interface. Thus, the WSII can enable high bandwidth buses and control signals between chips bonded to the WSII. The WSII can include one or more optical waveguides (not shown). The wafer interposer can also be used to couple additional boards, modules, components and so on. These further elements can be located on the opposite side of the wafer interposer from the bonded chiplets. The plurality of TSVs, such as TSV 1212, enable electrical connections between a front side of the WSII and a back side of the WSII. The TSVs can align with microbumps, C4s, ball grid arrays (BGAs), etc. associated with the plurality bonded chiplets.

The apparatus 1200 includes a plurality of chiplets, such as chiplet 1214. The chiplets can include a processor chiplet, a multi-core processor chiplet, a graphics processor chiplet, a system-on-a-chip, a memory chiplet, an application-specific integrated circuit (ASIC), an artificial intelligence (AI) or machine learning (ML) accelerator, a switching chiplet, a vertical-cavity surface-emitting laser (VCSEL), and so on. The chiplets, which can be chips, can include one or more input/output (I/O) chiplets such as chiplet 1216. The chiplets can include an integrated circuit designed for a flip-chip application. A chip design for a flip-chip application can include a chip for which connections to the chip are accomplished at the top layer of the chip. The connections can include positive and negative DC power connections, data connections, control connections, and so on. The various chip connections can include pads on the top layer of the chips. The chiplets can include a chip that can accomplish a processing function such as a deep learning function.

Various techniques can be used to make connections to the top of a chiplet. In a usage example, a technique based on micro-bumps can be used. A micro-bump can be associated with each connection point or pad on each chiplet. The micro-bumps can comprise a dense array of connection points or pads. The micro-bumps can include a material appropriate for mounting the chip to a substrate, a board, an interposer, and so on. The micro-bumps can include solder micro-bumps. These micro-bumps can be arranged in a ball grid array (BGA) or some other geometry. The WSII includes a plurality of through-silicon vias (TSVs) such as shown at 1212. The TSVs can provide a connection between the micro-bumps on the top side of the WSII and the connectors on the bottom side of the WSII. The TSV connections can be used to deliver power to the chiplets through the back side of the WSII.

The apparatus 1200 includes a plurality of modular power substrates (MPSs) 1220, wherein the plurality of MPSs is inserted into an isometric grid array (IGA) 1230, wherein a back side of the IGA includes a plurality of external compression pins 1232. An MPS can be coupled to one or more elements associated with the WSII. Each MPS in the plurality of MPSs can be coupled to one or more chiplets within the plurality of chiplets. Each MPS within the plurality of MPSs can be based on a form factor mirroring one or more corresponding chiplets within the plurality of chiplets on the front side of the WSII. The form factor of the MPS can be associated with or dependent on components mounted to the wafer interposer. In a usage example, the plurality of MPSs can be based on a form factor mirroring the corresponding functional chip. The form factor of the MPS can have a 1:1 relationship to the one or more corresponding chiplets, or can include other shape factors. The MPSs can be based on a variety of materials. In a usage example, one or more MPSs within the plurality of MPSs comprise an inorganic substrate. An inorganic substrate can include a silicon substrate, a glass substrate, and so on. In another usage example, one or more MPSs within the plurality of MPSs comprise an organic substrate. The organic substrates can include substrates such as printed circuit boards. Recall that the chiplets are mounted to the front or top side of the WSII. The plurality of MPSs can be coupled to a back side of the WSII.

The apparatus 1200 includes one or more elastomer sheets 1234, wherein the one or more elastomer sheets are compressed between one or more MPSs in the plurality of MPSs and one or more TSVs within the plurality of TSVs, by one or more compression plates and the plurality external compression pins. The plurality of elastomer sheets provides conduction paths between pads or contacts associated with the MPSs and corresponding pads or contacts associated with the WSII. The plurality of MPSs can include an I/O MPS such as I/O MPS 1222. One or more I/O MPSs can provide power to one or more I/O chips such as chiplet 1216. The I/O MPSs can further send data to or from and I/O chiplet, can control an I/O chiplet, and the like. Connection paths to the I/O chips, such as cable 1236, can escape a stack-up such as shown in apparatus 1200 by exiting the stack-up between the IGA 1230 and a unified control board (UCB) (described below). The cable 1236 can comprise an optical cable which can be driven by the I/O chiplet.

Each MPS within the plurality of MPSs can be coupled to other elements, such as a USB, with a socket such as shown at 1238. The socket can comprise a high-power socket, a high voltage socket, and so on. The coupling can include one or more plugs, pins, terminals, contacts, etc. from the MPS which can be inserted into the socket, which can be integrated into the UCB. In a usage example, the coupling can be based on a high voltage socket, wherein the high voltage socket transfers power from the UCB to the plurality of MPSs. The high voltage socket can be used to provide a first DC voltage. The first DC voltage can be provided by a DC-to-DC converter. The first DC voltage can be converted to a second DC voltage by one or more DC-to-DC converters. The coupling can accommodate a maximum lateral displacement of the UCB due to thermal expansion during operation. In a usage example, the mechanical connection can include a compliant connector. The lateral displacement can result from thermal expansion of the PWSI, the UCB, and/or the MPS during operation.

Recall that the isometric grid array can include a plurality of open recesses. The open recesses can include a variety of shapes, where the open recess shapes can include square, rectangular, circular, oval, honeycomb, and so on. Structures such as reinforcement structures can be added to one or more of the open recesses. In embodiments, the apparatus 1200 further comprises a plurality of reinforcement crossbars 1240 within one or more open recesses of the IGA. The reinforcement crossbars can reinforce the IGA, can be used to compress one or more MPSs within the plurality of MPSs, and so on. In embodiments, the plurality of reinforcement crossbars and the plurality of external compression pins enable planar compression. The reinforcement crossbars can come in contact with the MPSs to enable substantially planar compression across each MPS within the plurality of MPSs. The plurality of reinforcement crossbars can enable a compression force applied by the IGA to be distributed across each MPS. The compression force can then be transferred from each MPS to one or more elastomer sheets that couple the MPSs and the WSII. The reinforcement crossbars can be attached to IGA, fabricated on the IGA, and so on. In a usage example, the reinforcement crossbars can be deposited on the IGA. The depositing can be accomplished using techniques such as chemical vapor deposition techniques. In another usage example, the reinforcement crossbars can be glued to the IGA. The gluing can be accomplished using an epoxy, an ethyl cyanoacrylate, and so on. In embodiments, the IGA maintains a coplanarity of the WSII.

The apparatus 1200 includes a plurality of DC-to-DC power converters 1250, wherein the plurality of DC-to-DC power converters is coupled the plurality of MPSs via a plurality of sockets. The apparatus 1200 can include a unified control board (UCB) 1260, wherein the UCB includes the plurality of DC-to-DC converters. As described above, each DC-to-DC power converter in the plurality of DC-to-DC power converters can be coupled to a respective MPS in the plurality of MPSs. The connection between each DC-to-DC converter and a respective MPS can enable power transfer, control, and so on. The coupling between the plurality of DC-to-DC converters and the plurality of MPSs can remain reliable when the DC-to-DC converters and the MPSs are operating. The coupling can accommodate a maximum lateral displacement of the UCB due to thermal expansion during operation. The handling a maximum lateral displacement can be critical to maintaining reliable electrical connections between and among components, the WSII, one or more UCBs, one or more MPSs, and so on. The UCB can send DC power to the plurality of chiplets bonded to the WSII. The sending can be based on the plurality of MPSs and the plurality of TSVs. An MPS can include a connector (discussed above), where the connector can be used to couple the MPS to the UCB. For the apparatus 1200, the connector can comprise a socket on the UCB. The socket can comprise a high-power socket, a high voltage socket, and so on. The mechanical connection, electrical connection, and so on can include one or more plugs, pins, terminals, contacts, etc. from the MPS which can be inserted into the socket. The inserting can include a centerpiece, as described earlier, which can be at the intersection of the crossmembers within the reinforcement structure. In a usage example, the coupling can be based on a high voltage socket, wherein the high voltage socket transfers power from the UCB to the plurality of MPSs. The high voltage socket can be used to provide a first DC voltage that can be converted to a second DC voltage by one or more DC-to-DC converters. The coupling can accommodate a maximum lateral displacement of the UCB due to thermal expansion during operation. The lateral displacement can result from thermal expansion of the WSII, the UCB, and/or the MPS during operation. The UCB 1260 can include a digital controller chip (not shown). The DC-to-DC converters can be controlled by a control chip associated with the UCB. The digital controller chip can control power delivery to the plurality of chiplets. The controlling power delivery can include enabling or disabling power transfer, controlling conversion of an input voltage to and an output voltage from a DC-to-DC converter, and the like.

As explained above and throughout, the WSII and the UCB can expand at different rates due to different CTEs. Thus, the MPSs that are coupled to the UCB can also move, which can cause connections associated with the elastomer sheets between the WSII and the MPSs to become unreliable. To mitigate this movement due to expansion, as explained previously, the MPS can be designed modularly, effectively isolating movement between MPSs. In addition, the socket, which can be a high-power socket, a high voltage socket, etc., can comprise a compliant connector. In embodiments, the UCB 1260 comprises a plurality of UCB holes, wherein the plurality of external compression pins 1232 is inserted through the plurality of UCB holes. The UCB holes can enable the external compression pins to contact a second compression plate (explained below). The second compression plate and the first compression plate can compress the IGA, via the external compression pins. The compression can further compress the one or more elastomer sheets between the MPSs and the WSII, establishing and maintaining an electrical connection to provide back side power to the chiplets through the back side of the WSII.

The apparatus 1200 can include a first cold plate 1270. Further embodiments include a first cold plate, wherein the first cold plate is mounted to the plurality of chiplets, wherein the first cold plate is clamped, by one or more clamps 1292, to a first compression plate 1290 within the one or more compression plates. The first cold plate can be used to extract a portion of heat generated by chiplets as the chiplets operate. Recall that prodigious amounts of heat can be generated by chips and other electronic elements as they are operating. This point can be particularly relevant to high-performance chips. In embodiments, the first cold plate includes a plurality of internal compression pins 1282, wherein the internal compression pins stiffen the first cold plate. The internal compression pins can align with the external compression pins 1232 associated with the IGA. Thus, compression force can be transferred through the first cold plate without damaging or distorting the first cold plate.

The apparatus 1200 can include a second cold plate. Further embodiments include a second cold plate 1280, wherein the second cold plate is mounted to the plurality of DC-to-DC power converters. The DC-to-DC converters can also generate copious heat while the converters are operating. The second cold plate can remove at least a portion of this heat. The removal of a portion of the heat by the first cold plate, cold plate 1, and the second cold plate, cold plate 2, can help to protect the electronic elements to which the cold plates are coupled. In embodiments, the second cold plate (SCP) comprises a plurality of SCP holes, wherein the plurality of external compression pins 1232 are inserted through the plurality of SCP holes. The plurality of external compression pins that extend from the back side of the isometric grid array 1230 can pass through the SCP holes. The plurality of external compression pins can make contact with a second compression plate. Embodiments include a second compression plate within the one or more compression plates, wherein the second compression plate is mounted to the second cold plate, wherein the plurality of external compression pins contacts the second compression plate, and wherein the clamping is based on the second compression plate. The first compression plate 1290 and the second compression plate 1294 can compress the IGA, which in turn compresses the one or more elastomer sheets 1234 between the MPSs 1220 and the WSII 1210.

The external compression pins associated with the IGA can provide support for planar compression of the WSII when in contact with a compression plate. Without the external compression pins, when the IGA is compressed by one or more compression plates, the middle of the IGA may “sag,” providing less compression force than the edges of the IGA. In some circumstances, this can lead to an unreliable electrical connection between the MPSs and the WSII in the middle of the IGA, causing unreliable power delivery to the chiplets. As described earlier, the compression, which can be planar compression, can be based on one or more clamps 1292. The clamps can provide sufficient compression force throughout the IGA to maintain electrical coupling between the MPSs and the WSII. Both spring-loaded fasteners and clamps can be used.

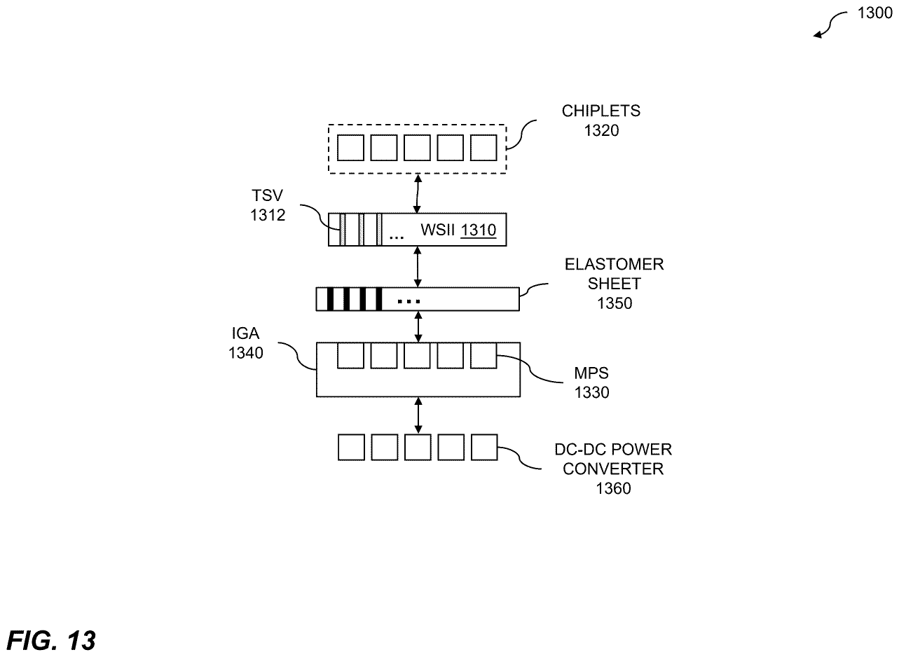

FIG. 13 is a system diagram for back side power delivery for wafer-scale integration with an isometric grid array with compression pins. Disclosed is a system for power delivery comprising: a wafer-scale integration interposer (WSII), wherein a front side of the WSII is bonded to a plurality of chiplets, wherein the WSII includes a plurality of through-silicon vias (TSVs); a plurality of modular power substrates (MPSs), wherein the plurality of MPSs is inserted into an isometric grid array (IGA), wherein a back side of the IGA includes a plurality of external compression pins; one or more elastomer sheets, wherein the one or more elastomer sheets are between the plurality of MPSs and the plurality of TSVs, and wherein the one or more elastomer sheets are compressed by one or more compression plates and the plurality of external compression pins; and a plurality of DC-to-DC power converters, wherein the plurality of DC-to-DC power converters are coupled to the plurality of MPSs via a plurality of sockets, and wherein the system, when provided DC power, is configured to: send DC power, by the plurality of DC-to-DC power converters, to the plurality of chiplets, wherein the sending is based on the plurality of MPSs, the one or more elastomer sheets, and the plurality of TSVs.

The system 1300 includes a wafer-scale integration interposer (WSII) 1310, wherein a front side of the WSII is bonded to a plurality of chiplets 1320, wherein the WSII includes a plurality of through-silicon vias (TSVs) 1312. The WSII can comprise an inorganic wafer such as a silicon wafer, a glass wafer, and so on. The WSII can include an organic wafer. A TSV can include an electrical connection that completely passes through a wafer such as a silicon wafer or a die. The plurality of TSVs is oriented vertically in order to enable connections between the front side of the WSII and the back side of the WSII. The plurality of chiplets can include general purpose chiplets such as processor chiplets, multiprocessor chiplets, graphics processor chiplets, memory chiplets, switching chiplets, application-specific integrated circuits (ASICS), systems-on-chip (SoCs), memory chiplets, artificial intelligence (AI) and machine learning (ML) accelerators, I/O chiplets, and so on. The plurality of chiplets can include optical chips such as VCSELs. The plurality of chiplets can create prodigious heat during operation. The heat can be due to current provided to the chiplets such as active current, overcurrent, leakage current, and so on. The heat can result from IR drops associated with interconnect, active devices, leakage current, etc. within the chiplets. The chiplets can be bonded to the WSII via micro-bumps, controlled collapse chip connections (C4s), and so on. The chiplets bonded to the WSII can be bonded to the TSVs, to interconnected associated with the WSII, and so on.

The system 1300 includes a plurality of modular power substrates (MPSs) 1330, wherein the plurality of MPSs is inserted into an isometric grid array (IGA) 1340, wherein a back side of the IGA includes a plurality of external compression pins. Each MPS within the plurality of MPSs can be based on a form factor mirroring one or more corresponding chiplets within the plurality of chiplets on the front side of the WSII. The IGA includes one or more open recesses into which the plurality of MPSs can be inserted. The open recesses can be square, rectangular, round, oval, hexagonal, and so on. Embodiments include stiffening the IGA, wherein the stiffening is based on a plurality of reinforcement crossbars within one or more open recesses within the IGA. In embodiments, the plurality of reinforcement crossbars and the plurality of external compression pins enable planar compression of the one or more elastomer sheets (described below). Maintaining coplanarity of the WSII can reduce the risk of the WSII fracturing or cracking under pressure applied by the IGA. In embodiments, the IGA maintains a coplanarity of the WSII.

The system 1300 includes one or more elastomer sheets 1350, wherein the one or more elastomer sheets are between the plurality of MPSs and the plurality of TSVs, and wherein the one or more elastomer sheets are compressed by one or more compression plates and the plurality of external compression pins. The elastomer sheets can include conductive connecting materials. The plurality of elastomer sheets enables attaching a plurality of modular power substrates (MPSs). The plurality of elastomer sheets can include a variety of materials, configurations, and so on. In some embodiments, a single elastomer sheet can be used. An elastomer sheet can include a plurality of conductive filaments such as brass, gold, etc. that are embedded in a sheet of silicone rubber or another suitable material. A portion of the filaments can align with contacts, pads, solder balls, and so on associated with the MPSs, the TSVs, and the like. The elastomer sheet can be held in place with a compression force. An adhesive backing can be added to the elastomer sheet. The elastomer sheet can provide conduction paths between the MPSs and the TSVs within the WSII.

The system 1300 includes a plurality of DC-to-DC power converters 1360, wherein the plurality of DC-to-DC power converters are coupled to the plurality of MPSs via a plurality of sockets. The DC-to-DC converters can convert DC power from a high DC voltage range, such as 48 volts to 54 volts, to a lower DC voltage range, such as 12 volts to 13.5 volts. The MPSs can include a plurality of DC-to-DC power converters which can perform a second voltage conversion. The second voltage conversion can produce a DC voltage below a threshold such as 1 volt.

In embodiments, the plurality of DC-to-DC power converters 1360 comprises a unified circuit board (UCB). The UCB can be coupled to the plurality of MPSs. The UCB can include the plurality of DC-to-DC converters. The coupling can be based on a high-power socket (which can be a high voltage socket). The USB can include one or more control circuits. The control circuits can be used to generate control signals to one or more chiplets, enable transfers of data, control DC-to-DC converters, and the like.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system”—may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for power delivery comprising:
accessing a wafer-scale integration interposer (WSII), wherein a front side of the WSII is bonded to a plurality of chiplets, wherein the WSII includes a plurality of through-silicon vias (TSVs);
inserting, into an isometric grid array (IGA), a plurality of modular power substrates (MPSs), wherein a back side of the IGA includes a plurality of external compression pins;
coupling the plurality of MPSs to the plurality of chiplets, wherein the coupling includes compressing, by one or more compression plates, one or more elastomer sheets between the plurality of MPSs and the plurality of TSVs, wherein the compressing is based on the plurality of external compression pins;
coupling the plurality of MPSs to a plurality of DC-to-DC power converters, wherein the coupling is based on a plurality of sockets; and
sending DC power, by the plurality of DC-to-DC power converters, to the plurality of chiplets, wherein the sending is based on the plurality of MPSs, the one or more elastomer sheets, and the plurality of TSVs.

2. The method of claim 1 further comprising mounting a first cold plate to the plurality of chiplets.

3. The method of claim 2 wherein the first cold plate includes a plurality of internal compression pins, wherein the internal compression pins stiffen the first cold plate.

4. The method of claim 2 further comprising clamping, based on one or more clamps, the first cold plate to a first compression plate within the one or more compression plates.

5. The method of claim 4 wherein the clamping is based on a second compression plate within the one or more compression plates, wherein the plurality of external compression pins contacts the second compression plate.

6. The method of claim 5 wherein the plurality of DC-to-DC power converters comprises a unified control board (UCB).

7. The method of claim 6 wherein the clamping includes inserting, through a plurality of holes within the UCB, the plurality of external compression pins.

8. The method of claim 7 further comprising mounting a second cold plate to the plurality of DC-to-DC power converters.

9. The method of claim 8 wherein the clamping includes inserting, through a plurality of holes within the second cold plate, the plurality of external compression pins.

10. The method of claim 1 further comprising stiffening the IGA, wherein the stiffening is based on a plurality of reinforcement crossbars within one or more open recesses within the IGA.

11. The method of claim 10 wherein the plurality of reinforcement crossbars and the plurality of external compression pins enable planar compression of the one or more elastomer sheets.

12. The method of claim 1 wherein the sending includes delivering the DC power, by the plurality of DC-to-DC power converters, to the plurality of MPSs, wherein the delivering includes a first voltage conversion.

13. The method of claim 12 further comprising transferring the DC power that was delivered, by the plurality of MPSs, to the plurality of chiplets, wherein the transferring includes a second voltage conversion.

14. The method of claim 1 wherein the IGA maintains a coplanarity of the WSII.

15. An apparatus for power delivery comprising:
a wafer-scale integration interposer (WSII), wherein a front side of the WSII is bonded to a plurality of chiplets, wherein the WSII includes a plurality of through-silicon vias (TSVs);
a plurality of modular power substrates (MPSs), wherein the plurality of MPSs is inserted into an isometric grid array (IGA), wherein a back side of the IGA includes a plurality of external compression pins;
one or more elastomer sheets, wherein the one or more elastomer sheets are compressed between one or more MPSs in the plurality of MPSs and one or more TSVs within the plurality of TSVs, by one or more compression plates and the plurality of external compression pins; and
a plurality of DC-to-DC power converters, wherein the plurality of DC-to-DC power converters is coupled the plurality of MPSs via a plurality of sockets.

16. The apparatus of claim 15 further comprising a first cold plate, wherein the first cold plate is mounted to the plurality of chiplets, wherein the first cold plate is clamped, by one or more clamps, to a first compression plate within the one or more compression plates.

17. The apparatus of claim 16 further comprising a unified control board (UCB), wherein the UCB includes the plurality of DC-to-DC power converters.

18. The apparatus of claim 17 wherein the UCB comprises a plurality of UCB holes, wherein the plurality of external compression pins is inserted through the plurality of UCB holes.

19. The apparatus of claim 17 further comprising a second cold plate, wherein the second cold plate is mounted to the plurality of DC-to-DC power converters.

20. The apparatus of claim 19 wherein the second cold plate (SCP) comprises a plurality of SCP holes, wherein the wherein the plurality of external compression pins is inserted through the plurality of SCP holes.

21. The apparatus of claim 20 further comprising a second compression plate within the one or more compression plates, wherein the second compression plate is mounted to the second cold plate, wherein the plurality of external compression pins contacts the second compression plate, and wherein the clamping is based on the second compression plate.

22. The apparatus of claim 15 further comprising a plurality of reinforcement crossbars within one or more open recesses of the IGA.

23. The apparatus of claim 22 wherein the plurality of reinforcement crossbars and the plurality of external compression pins enable planar compression.

24. A system for power delivery comprising:
a wafer-scale integration interposer (WSII), wherein a front side of the WSII is bonded to a plurality of chiplets, wherein the WSII includes a plurality of through-silicon vias (TSVs);
a plurality of modular power substrates (MPSs), wherein the plurality of MPSs is inserted into an isometric grid array (IGA), wherein a back side of the IGA includes a plurality of external compression pins;
one or more elastomer sheets, wherein the one or more elastomer sheets are between the plurality of MPSs and the plurality of TSVs, and wherein the one or more elastomer sheets are compressed by one or more compression plates and the plurality of external compression pins; and
a plurality of DC-to-DC power converters, wherein the plurality of DC-to-DC power converters are coupled to the plurality of MPSs via a plurality of sockets, and wherein the system, when provided DC power, is configured to:
send DC power, by the plurality of DC-to-DC power converters, to the plurality of chiplets, wherein the sending is based on the plurality of MPSs, the one or more elastomer sheets, and the plurality of TSVs.
